(19) United States
(12) Patent Application Publication
(10) Pub. No.: US 2025/0323137 A1
(43) Pub. Date: Oct. 16, 2025

(54) CHIP ON FILM AND DISPLAY APPARATUS

(71) Applicant: BOE Technology Group Co., Ltd., Beijing (CN)

(72) Inventors: Shuilang DONG, Beijing (CN); Yan QU, Beijing (CN); Xinhong LU, Beijing (CN); Guoteng LI, Beijing (CN); Liuqing LI, Beijing (CN); Jingshang ZHOU, Beijing (CN); Baoman LI, Beijing (CN)

(21) Appl. No.: 18/866,122

(22) PCT Filed: Sep. 29, 2022
(86) PCT No.: PCT/CN2022/122676

§ 371 Date: Nov. 15, 2024

(51) Int. Cl. H01L 23/498; G02F 1/1368

(52) U.S. Cl. CPC H01L 23/49838; G02F 1/1368

(57) ABSTRACT

The present disclosure provides a chip on film and a display apparatus, the chip on film includes a base substrate, which includes: a plurality of bonding areas and a peripheral area arranged around the bonding areas; a plurality of bonding pads located on the base substrate, and each bonding area is provided with multiple bonding pads; and an accompanying plated pattern, which is located in a same layer and made of a same material as the plurality of bonding pads, and is located in a part of the peripheral area on at least one side of the bonding areas.

### TECHNICAL FIELD

The present disclosure relates to the field of display technology, and in particular to a chip on film and a display apparatus.

### BACKGROUND

Large-sized electronic products such as liquid crystal displays, liquid crystal televisions and plasma televisions, and medium-sized and small-sized electronic products such as mobile phones, digital cameras and the like are all developing towards lightweight, thin, and short and small size, so that a new generation of packaging technology, which supports high density and small volume and can be freely installed, is required to meet such requirements. Therefore, chip On Film (COF) packaging technology has been developed. The COF is formed by bonding a driver chip (a source driver chip IC or a gate driver chip IC) to a flexible wiring board on which a wiring pattern is formed and installing the driver chip on the flexible wiring board. The wiring pattern of the COF generally includes inner leads connected to pins of the driver chip and outer leads connected to an external circuit.

### SUMMARY

Embodiments of the present disclosure provide a chip on film and a display apparatus as follows.

In one aspect, an embodiment of the present disclosure provides a chip on film, including:
a base substrate having a plurality of bonding areas and at least one peripheral area arranged around each bonding area;
a plurality of bonding pads located on the base substrate, and each bonding area is provided with multiple bonding pads; and
at least one accompanying plated pattern, which is located in a same layer and made of a same material as the plurality of bonding pads, and is located in a part of the peripheral area on at least one side of the bonding area.

In some implementations, in the chip on film provided by the embodiment of the present disclosure, in each of the bonding areas, the pads are arranged in a plurality of rows along an extending direction in which the pads extend, the peripheral areas includes a first peripheral area adjacent to a first row of pads and a second peripheral area adjacent to a last row of pads, and the accompanying plated pattern includes first accompanying plated patterns located in the first peripheral area and/or the second peripheral area.

In some implementations, in the chip on film provided in the embodiment of the present disclosure, the first accompanying plated patterns correspond to the pads in the first row and/or the pads in the last row one by one, and each first accompanying plated pattern and the pad corresponding to the first accompanying plated pattern are formed into one piece.

In some implementations, in the chip on film provided in the embodiment of the present disclosure, one of the plurality of bonding areas includes a first bonding sub-area and a second bonding sub-area arranged side by side in an extending direction in which the pads extend; and
the peripheral area further includes a third peripheral area located between the first bonding sub-area and the second bonding sub-area, and the accompanying plated pattern include a plurality of second accompanying plated patterns located in the third peripheral area.

In some implementations, the chip on film provided in the embodiment of the present disclosure further includes a plurality of supporting patterns located in the third peripheral area.

In some implementations, in the chip on film provided in the embodiment of the present disclosure, the third peripheral area includes a first edge area adjacent to the first bonding sub-area and a second edge area adjacent to the second bonding sub-area;
the chip on film further includes at least two groups of common lines, each group of common lines including a first common line and a second common line, the first common line extending in the first edge area after being led out from the second bonding sub-area, and the second common line extending in the second edge area after being led out from the second bonding sub-area; and
in a pattern set formed by the plurality of supporting patterns and the plurality of second accompanying plated patterns, the supporting patterns and the second accompanying plated patterns are uniformly distributed in an area between the groups of common lines and an area between the first common line and the second common line in each group of common lines.

In some implementations, in the chip on film provided in the embodiment of the present disclosure, each supporting pattern of the plurality of supporting patterns and one of a portion of the second accompanying plated patterns corresponding to the supporting pattern are formed into one piece.

In some implementations, in the chip on film provided by the embodiment of the present disclosure, in a combined pattern of the supporting patterns and the second accompanying plated pattern which are formed into one piece, the supporting patterns are symmetrical with respect to a central axis of the combined pattern extending in a direction intersecting the extending direction in which the pads extend.

In some implementations, in the chip on film provided in the embodiment of the present disclosure, the second accompanying plated patterns spaced apart from the supporting patterns are independent patterns, and the combined patterns are uniformly distributed in the area between the groups of common lines and the area between the first common line and the second common line in each group of common lines.

In some implementations, in the chip on film provided in the embodiment of the present disclosure, in the extending direction in which the pads extend, a length of each combined pattern and a length of each independent pattern each are more than 50% of a distance between the first common line and the second common line.

In some implementations, in the chip on film provided in the embodiment of the present disclosure, the second accompanying plated patterns spaced apart from the supporting patterns are independent patterns, the combined patterns form at least one row, the independent patterns forms at least two rows, the at least one row of combined patterns and the at least two rows of independent patterns are arranged in the extending direction in which the pads extend, and the row of the combined patterns is farther away from the first edge area and the second edge area than the rows of the independent patterns.

In some implementations, in the chip on film provided in the embodiment of the present disclosure, a shape and a width of each combined pattern and a shape and a width of each independent pattern are substantially the same as a shape and a width of each pad, respectively.

In some implementations, in the chip on film provided in the embodiment of the present disclosure, the second accompanying plated patterns spaced apart from the supporting patterns are independent patterns, the combined patterns are arranged in at least one row, and the independent patterns are strip-shaped accompanying plated patterns between an area where the combined patterns are located and the first bonding sub-area, and between the area where the combined patterns are located and the second bonding sub-area; and
in the direction intersecting the extending direction in which the pads extend, a length of the strip-shaped accompanying plated pattern is larger than or equal to a distance between a first pad and a last pad of the row of pads.

In some implementations, in the chip on film provided in the embodiment of the present disclosure, a length of each first accompanying plated pattern in the extending direction in which the pads extend is greater than or equal to 300 μm and less than or equal to 1000 μm.

In some implementations, in the chip on film provided by the embodiment of the present disclosure, the at least one peripheral area includes a fourth peripheral area and a fifth peripheral area, the fourth peripheral area and the fifth peripheral area extend in the extending direction in which the pads extend, and in a direction intersecting the extending direction in which the pads extend, the fourth peripheral area and the fifth peripheral area are located on both sides of the bonding areas;
the chip on film further includes alignment marks located in the fourth peripheral area and the fifth peripheral area, and the alignment marks and the pads are arranged in a same layer and made of a same material; and
the at least one accompanying plated pattern includes a third accompanying plated pattern located in the fourth peripheral area and/or the fifth peripheral area, each third accompanying plated pattern surrounds at least one of edges of the alignment mark at two sides of the alignment mark in the extending direction in which the pads extend, a side of the alignment mark away from the bonding areas, and third accompanying plated pattern is spaced apart from the alignment mark by a preset distance.

In some implementations, in the chip on film provided in the embodiment of the present disclosure, the third accompanying plated pattern is a block pattern.

In some implementations, in the chip on film provided in the embodiment of the present disclosure, the third accompanying plated pattern includes a plurality of strip-shaped patterns sequentially arranged in the extending direction in which the pads extend.

In some implementations, in the chip on film provided in the embodiment of the present disclosure, at both sides of the alignment mark in the direction intersecting the extending direction in which the pads extend, each third accompanying plated pattern respectively has a length greater than or equal to 1 mm and less than or equal to 5 mm in the direction intersecting the extending direction in which the pads extend.

In some implementations, in the chip on film provided by the embodiment of the present disclosure, in the direction intersecting the extending direction in which the pad extend, a distance from an end surface of the third plating accompanied patter away from the bonding area to the bonding area is substantially equal to a length of the first accompanying plated pattern.

In some implementations, in the chip on film provided by the embodiment of the present disclosure, the chip on film further includes a first protective pattern on a side of a layer where the plurality of pads are located away from the base substrate, where an orthographic projection of the first protective pattern on the base substrate overlaps with orthographic projections of the first accompanying plated pattern and the third accompanying plated pattern on the base substrate, the first accompanying plated pattern and the third accompanying plated pattern being arranged side by side in the direction intersecting the extending direction in which the pads extend, and in the extending direction in which the pads extend, the orthographic projection of the first protective pattern on the base substrate is spaced apart from the bonding areas by a preset distance.

In some implementations, in the chip on film provided in the embodiment of the present disclosure, the plurality of bonding areas include a first bonding area for bonding a display substrate and a second bonding area for bonding a circuit board.

In some implementations, in the chip on film provided in the embodiment of the present disclosure, in each of the first bonding area and the second bonding area, two adjacent rows of pads are partially staggered in a direction intersecting the extending direction in which the pads extend.

In some implementations, the chip on film provided in the embodiment of the present disclosure further includes a second protective pattern, the second protective pattern and the first protective pattern being formed into one piece, where an orthographic projection of the second protective pattern on the base substrate overlaps the orthographic projection of the third accompanying plated pattern on the base substrate, and in a direction intersecting the extending direction in which the pads extend, the orthographic projection of the second protective pattern on the base substrate is spaced apart from each of the bonding areas by a preset distance.

In some implementations, in the chip on film provided in the embodiment of the present disclosure, the plurality of bonding areas include a third bonding area for bonding a driver chip.

In some implementations, in the chip on film provided in the embodiment of the present disclosure, the third bonding area includes a first bonding sub-area and a second bonding sub-area, and in each of the first bonding sub-area and the second bonding sub-area, two adjacent rows of pads are partially staggered in a direction intersecting an extending direction in which the pads extend;
in the direction intersecting the extending direction in which the pads extend, the second bonding sub-area includes a first signal output area and a second signal output area which are arranged side by side, and a signal input area located between the first signal output area and the second signal output area; and
the first bonding sub-area includes a third signal output area and a fourth signal output area, the third signal output area and the first signal output area being arranged side by side in the extending direction in which the pads extend, and the fourth signal output area and the second signal output area being arranged side by side in the extending direction in which the pads extend.

On the other hand, an embodiment of the present disclosure provides a display apparatus, including a display substrate, a circuit board, a driver chip, and a chip on film, where the chip on film is the chip on film provided in the embodiment of the present disclosure, and the chip on film includes bonding areas corresponding to the display substrate, the driver chip, and the circuit board one to one.

### BRIEF DESCRIPTION OF DRAWINGS

FIG. 1 is a schematic diagram of a thicker pad at an edge of a bonding area according to an embodiment of the present disclosure;

FIG. 2 is a schematic diagram of an area where a thicker pad is located in a bonding area for bonding a display substrate or a flexible circuit board according to an embodiment of the present disclosure;

FIG. 3 is a schematic diagram of an area where a thicker pad is located in a bonding area for bonding a driver chip according to an embodiment of the present disclosure;

FIG. 4 is a schematic structural diagram of a chip on film according to an embodiment of the present disclosure;

FIG. 5 is a schematic structural diagram of a chip on film according to an embodiment of the present disclosure;

FIG. 6 is an enlarged structural diagram of an area M₁ in FIG. 5;

FIG. 7 is an enlarged structural diagram of an area M₂ in FIG. 5;

FIG. 8 is an enlarged structural diagram of an area M₃ in FIG. 5;

FIG. 9 is an enlarged structural diagram of an area M₂ in FIG. 5;

FIG. 10 is an enlarged structural diagram of an area M₂ in FIG. 5;

FIG. 11 is an enlarged structural diagram of an area M₁ in FIG. 5;

FIG. 12 is an enlarged structural diagram of an area M₂ in FIG. 5;

FIG. 13 is an enlarged structural diagram of an area M₁ in FIG. 5;

FIG. 14 is an enlarged structural diagram of an area M₂ in FIG. 5;

FIG. 15 is an enlarged structural diagram of an area M₃ in FIG. 5;

FIG. 16 is an enlarged structural diagram of an area M₂ in FIG. 5;

FIG. 17 is an enlarged structural diagram of an area M₂ in FIG. 5;

FIG. 18 is an enlarged structural diagram of an area M₁ in FIG. 5;

FIG. 19 is an enlarged structural diagram of an area M₂ in FIG. 5;

FIG. 20 is a schematic diagram of a structure formed during manufacturing a chip on film according to an embodiment of the present disclosure;

FIG. 21 is a schematic diagram of a partial structure of a layer where a lead is located according to an embodiment of the present disclosure;

FIG. 22 is a cross-sectional view of a structure in FIG. 21 taken along a line I-I′;

FIG. 23 is a schematic structural diagram of a layer where a lead is located according to an embodiment of the present disclosure;

FIG. 24 is an enlarged structural view of an area M4 in FIG. 23;

FIG. 25 is a schematic diagram of a structure formed during manufacturing a chip on film according to an embodiment of the present disclosure;

FIG. 26 is a schematic diagram of a structure formed during manufacturing a chip on film according to an embodiment of the present disclosure;

FIG. 27 is a schematic diagram of a structure formed during manufacturing a chip on film according to an embodiment of the present disclosure;

FIG. 28 is a schematic diagram of a structure formed during manufacturing a chip on film according to an embodiment of the present disclosure;

FIG. 29 is a schematic diagram of a structure formed during manufacturing a chip on film according to an embodiment of the present disclosure;

FIG. 30 is a schematic diagram of a structure formed during manufacturing a chip on film d according to an embodiment of the present disclosure;

FIG. 31 is a schematic structural diagram of a display apparatus according to an embodiment of the present disclosure;

FIG. 32 is a schematic structural diagram illustrating bonding of the display substrate or the flexible circuit board with a chip on film according to an embodiment of the present disclosure;

FIG. 33 is a schematic structural diagram illustrating bonding of a driver chip with a chip on film according to an embodiment of the present disclosure;

FIG. 34 is a schematic structural diagram illustrating bonding of a driver chip with a chip on film according to an embodiment of the present disclosure;

FIG. 35 is a schematic structural diagram of a display apparatus according to an embodiment of the present disclosure; and

FIG. 36 is a schematic structural diagram of a display apparatus according to an embodiment of the present disclosure.

### DETAIL DESCRIPTION OF EMBODIMENTS

To make the objects, technical solutions and advantages of the embodiments of the present disclosure more apparent, the technical solutions of the embodiments of the present disclosure will be clearly and completely described below with reference to the drawings of the embodiments of the present disclosure. It should be noted that the sizes and shapes of various figures in the drawings are not to scale, but are merely intended to schematically illustrate the present disclosure. Moreover, like reference numerals refer to like or similar elements or elements having like or similar functions throughout. To maintain the following description of the embodiments of the present disclosure clear and concise, detailed descriptions of known functions and known components are omitted from the present disclosure.

Unless defined otherwise, technical or scientific terms used herein shall have the ordinary meaning as understood by one of ordinary skill in the art to which the present disclosure belongs. The terms “first”, “second”, and the like, as used in the description and in the claims, do not denote any order, quantity, or importance, but rather are used to distinguish one element from another. The word “comprising/including”, “comprises/includes”, or the like means that the element or item preceding the word includes the element or item listed after the word and its equivalent, but does not exclude other elements or items. The terms “inner/in/inside”, “outer/out/outside”, “upper/on/above”, “lower/below/under”, and the like are used merely to indicate relative positional relationships, and when the absolute position of the object being described is changed, the relative positional relationships may also be changed accordingly.

With the continuous development of three-dimensional (3D) display technology, the market demand for 3D display products is rapidly increasing, and the resolution being continuously improved (for example, 16K, 32K, etc.) for supporting the information amount of the 3D display is a main development trend of the 3D display products; in order to support technologies such as multi-View (View) and X-Zone, the number of data channels desired by the 3D display products is greatly increased, and thus a COF packaging process with higher resolution is desired to meet the transmission of a huge amount of data. At present, COF products in the market are manufactured by a roll-to-roll process. However, the roll-to-roll process has a low process precision, copper (Cu) is adopted for the metal of the COF product, so that the wiring pitch is large, which cannot meet the requirements of the 3D display products with the source pins more than 5000.

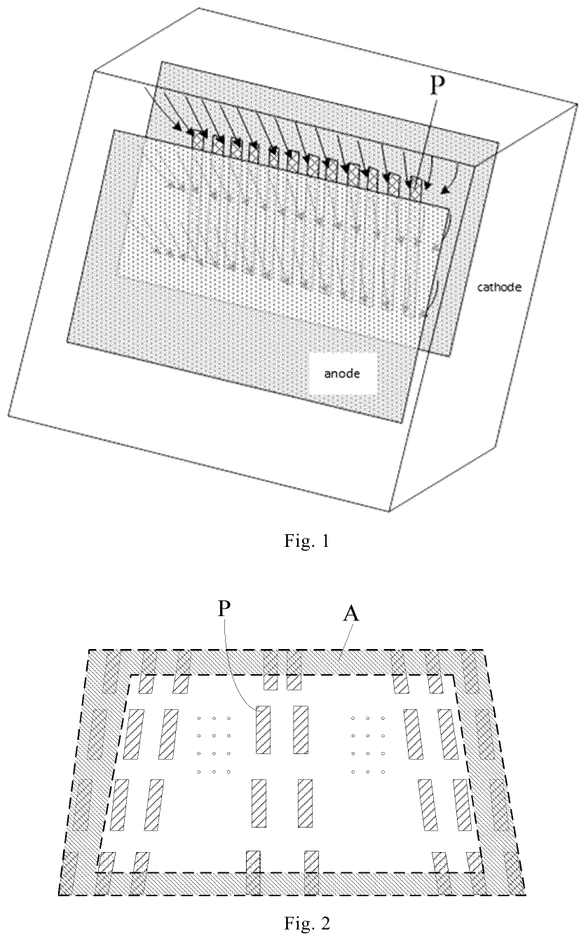

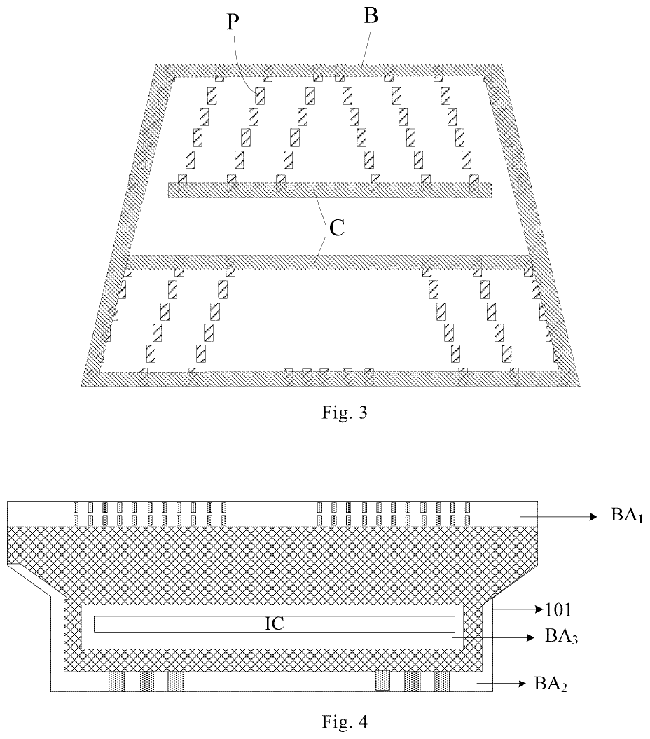

In view of above, the inventors form leads and pads in layers on a flexible substrate (PI), where each lead has a laminated structure composed of a titanium metal layer/an aluminum metal layer/a titanium metal layer, which are stacked, and each pad has a single-layer structure made of copper. A manufacturing scheme for COF having more than 10000 data pins (source pins) can be realized by designing multiple rows of pads. In the scheme, a thickness of a copper layer of the pad is desired to be more than 5 micrometers (μm), and a pitch between any two adjacent pads is less than 30μm, so that the pad can only be formed by a semi-additive electroplating process. However, a small area of the pad may lead to an uneven proportion of copper in a partial area of the pad, resulting in, during the electroplating process, concentrated power lines and increased current density around the pad (P), and a thicker pad (P) close to an edge, resulting in a significant thickness difference between the pads, which can easily lead to poor bonding, as shown in FIG. 1. Specifically, as shown in FIG. 2, in a bonding area (OLB Bonding) for bonding the display substrate (panel) and a bonding area (FPC Bonding) for bonding the flexible circuit board (FPC), the pad P in an edge area A is thicker than the pad in other area by 2 μm, which easily causes poor bonding. In addition, as shown in FIG. 3, in an bonding area (ILB Bonding) for bonding the driver chip (IC), the pads in an edge area B and a middle area C are thicker than the pads in other areas, which may cause poor bonding.

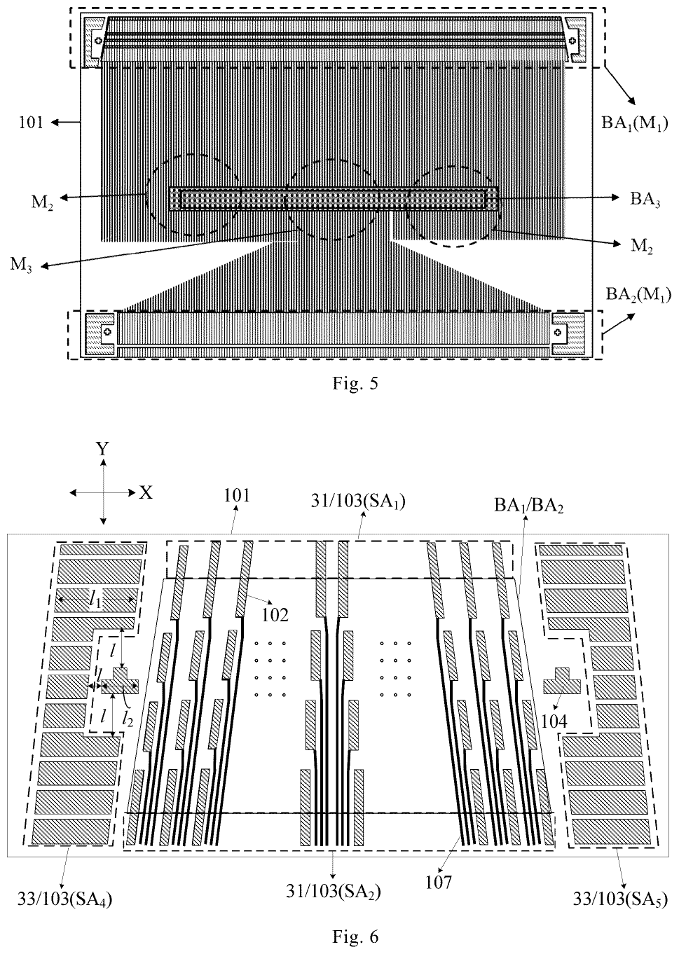

In order to solve the above technical problems in the related art, an embodiment of the present disclosure provides a chip on film, as shown in FIGS. 4 to 8, including:
a base substrate 101, the base substrate 101 including a plurality of bonding areas (e.g., a first bonding area BA₁ for bonding a display substrate, a second bonding area BA₂ for bonding a flexible circuit board, and a third bonding area BA₃ for bonding a driver chip), and at least one peripheral area (e.g., a first peripheral area SA₁, a second peripheral area SA₂, a third peripheral area SA₃, a fourth peripheral area SA₄, a fifth peripheral area SA₅) provided around the bonding area (e.g., the first bonding area BA₁, the second bonding area BA₂, the third bonding area BA₃), where the base substrate 101 may be a flexible base substrate made of polyimide or the like;
a plurality of pads 102 located on the base substrate 101, where each bonding area (for example, the first bonding area BA₁, the second bonding area BA₂, and the third bonding area BA₃) is provided therein with multiple pads 102, and a material of the pads 102 may be copper or the like; and
at least one accompanying plated pattern 103 disposed in a same layer and made of a same material as the plurality of pads 102, where the at least one accompanying plated pattern 103 is located in the peripheral area (e.g., the first peripheral area SA₁, the second peripheral area SA₂, the third peripheral area SA₃, the fourth peripheral area SA₄, and the fifth peripheral area SA₅) on at least one side of the bonding area (e.g., the first bonding area BA₁, the second bonding area BA₂, and the third bonding area BA₃).

In the above chip on film provided by the embodiment of the present disclosure, during the process of forming the pads 102 in the bonding area (e.g., the first bonding area BA₁, the second bonding area BA₂, and the third bonding area BA₃) by electroplating, the accompanying plated pattern 103 in the same layer and made of the same material as the pads 102 may be simultaneously formed in the peripheral area (e.g., the first peripheral area SA₁, the second peripheral area SA₂, the third peripheral area SA₃, the fourth peripheral area SA₄, and the fifth peripheral area SA₅). Since the peripheral area (e.g., the first peripheral area SA₁, the second peripheral area SA₂, the third peripheral area SA₃, the fourth peripheral area SA₄ and the fifth peripheral area SA₅) where the accompanying plated pattern 103 is located is located at the periphery of the bonding area (e.g., the first bonding area BA₁, the second bonding area BA₂ and the third bonding area BA₃) where the pads 102 are located, a phenomenon of concentrated power lines and a high current density may occur in the peripheral area (e.g., the first peripheral area SA₁, the second peripheral area SA₂, the third peripheral area SA₃, the fourth peripheral area SA₄ and the fifth peripheral area SA₅) during the plating process, so that the power lines and the current density of the bonding area (e.g., the first bonding area SA₁, the second bonding area BA₂ and the third bonding area BA₃) can be normal, and the pads 102 each having a uniform thickness can be formed in the bonding area (e.g., the first bonding area BA₁, the second bonding area BA₂ and the third bonding area BA₃) to improve the bonding yield. In some implementations of the present disclosure, a difference between the thicknesses of the pads 102 in the bonding area (e.g., the first bonding area BA₁, the second bonding area BA₂, the third bonding area BA₃) may be less than 1 μm.

In some implementations, in the above chip on film provided in the embodiments of the present disclosure, as shown in FIGS. 6 to 8, in each bonding area (e.g., the first bonding area BA₁, the second bonding area BA₂, and the third bonding area BA₃), the pads 102 are arranged in a plurality of rows along an extending direction Y in which the pads 102 extend, the at least one peripheral area includes the first peripheral area SA₁ on a side of the bonding area where a first row of pads 102 are located, and the second peripheral area SA₂ on a side of the bonding area where a last row of pads 102 are located, and the at least one accompanying plated pattern 103 includes first accompanying plated patterns 31 located in the first peripheral area SA₁ and/or the second peripheral area SA₂. Since the first row of pads 102 and the last row of pads 102 are located at an edge area of each bonding area (e.g., the first bonding area BA₁, the second bonding area BA₂, and the third bonding area BA₃), the edge area being an area where the power lines are concentrated and the current density is great during the electroplating process, thus an end, away from the bonding area (e.g., the first bonding area BA₁, the second bonding area BA₂, and the third bonding area BA₃), of each of the pads 102 in the first row and the last row is prone to be relatively thick. By providing the first accompanying plated pattern 31 in the first peripheral area SA₁ on the side of the bonding area where the first row of pads 102 are located and/or the second peripheral area SA₂ on the side of the bonding area where the last row of pads 102 are located, the area where the power lines are concentrated and the current density is great is transferred to the first peripheral area SA₁ and/or the second peripheral area SA₂, so that, in the edge area where the first row of pads 102 and the last row of pads 102 are located, the power lines are not concentrated and the current density is normal, therefore, the first row of pads 102 and the last row of pads 102 each have uniform thickness.

In some implementations, in the chip on film provided in the embodiment of the present disclosure, as shown in FIGS. 6 to 8, the first accompanying plated patterns 31 may correspond to the pads 102 in the first row and/or the pads 102 in the last row one to one, and each first accompanying plated pattern 31 and the pad 102 corresponding to the first accompanying plated pattern 31 are formed into one piece. In other words, the pads 102 in the first row and/or the pads 102 in the last row may be extended toward the first peripheral area SA₁ and/or the second peripheral area SA₂, and portions of the pads in the first row and/or portions of the pads 102 in the last row extending into the first peripheral area SA₁ and/or the second peripheral area SA₂ may serve as the first accompanying plated patterns 31. In consideration of the fact that, during the electroplating process in the related art, an area with concentrated power lines and great current density has a width about 200 μm, in order to ensure that the pads 102 are arranged to completely avoid the area with concentrated power lines and great current density, a length of the first accompanying plated pattern 31 in the extending direction, i.e., the Y direction, in which the pads 102 extend may be equal to or greater than 300 μm and equal to or less than 1000 μm in the present disclosure, for example, the length of the first accompanying plated pattern 31 in the extending direction, i.e., the Y direction, in which the pads 102 extend may be 300 μm, 400 μm, 500 μm, 600 μm, 700 μm, 800 μm, 900 μm, 1000 μm, and the like.

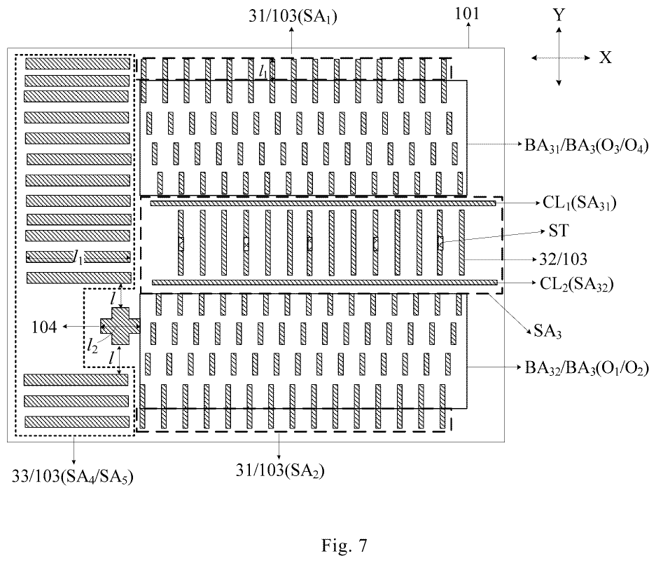

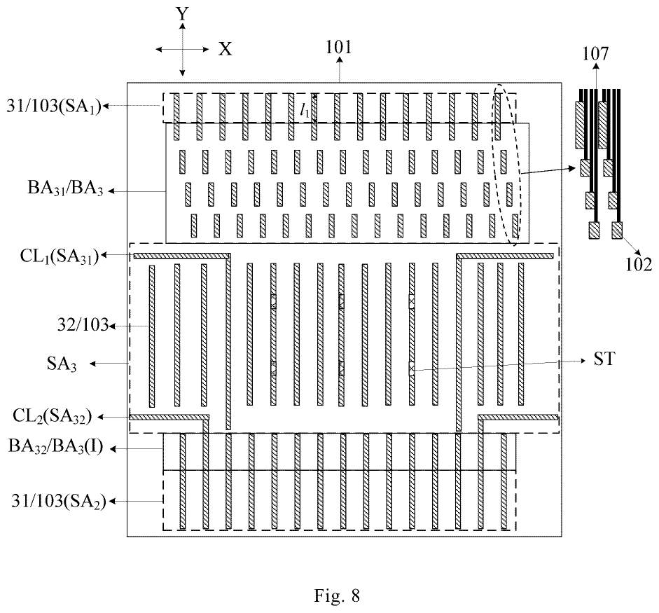

In some implementations, in the chip on film provided in the embodiment of the present disclosure, as shown in FIG. 7 and FIG. 8, one bonding area (for example, the third bonding area BA3) of the bonding areas (for example, the first bonding area BA₁, the second bonding area BA₂, and the third bonding area BA₃) includes a first bonding sub-area BA₃₁ and a second sub-bonding sub-area BA₃₂ which are arranged side by side in the extending direction (the Y direction) in which the pads 102 extend, a row of pads 102 in the first bonding sub-area BA₃₁ farthest away from the second bonding sub-area BA₃₂ is a first row of pads 102 in the bonding area (for example, the third bonding area BA₃), and a row of pads 102 in the second bonding sub-area BA₃₂ farthest away from the first bonding sub-area BA₃₁ is a last row of pads 102 in the bonding area (for example, the third bonding area BA₃). The at least one peripheral area may further include a third peripheral area SA₃ located between the first bonding sub-area BA₃₁ and the second bonding sub-area BA₃₂. Since the pads 102, adjacent to the third peripheral area SA₃, in the first bonding sub-area BA₃₁ and the second bonding sub-area BA₃₂ are prone to have a non-uniform thickness, in order to ensure that the thicknesses of the pads 102 on both sides of the third peripheral area SA₃ are uniform, as shown in FIGS. 7 and 8, the accompanying plated pattern 103 may be configured to include a plurality of second accompanying plated patterns 32 located in the third peripheral area SA₃. Alternatively, a ratio of a sum of areas of orthographic projections of all the second accompanying plated patterns 32 on the base substrate 101 to an area of the third peripheral area SA₃ is less than 50%, for example, about 40%, such as 45%, 40%, 35% and 30%.

In some implementations, as shown in FIGS. 7 to 10, the chip on film provided in the embodiment of the present disclosure may further include a plurality of supporting patterns ST for supporting the driver chip IC, balancing the bonding pressure, and the supporting patterns ST may not loaded with any electrical signal. In some implementations, the plurality of supporting patterns ST are located in the third peripheral area SA₃, a ratio of a sum of areas of orthographic projections of the plurality of supporting patterns ST on the base substrate 101 to a sum of areas of orthographic projections of gaps between the supporting patterns ST on the base substrate 101 is less than or equal to 1/9. That is to say, the sum of the areas of the orthographic projections of all the supporting patterns ST on the base substrate 101 to the area of the third peripheral area SA₃ is less than 10%, for example, 10%, 9%, 8%, and the like. Alternatively, the second accompanying plated patterns 32 are provided at gaps between the supporting patterns ST. In some implementations, a ration of a sum of areas of all the second accompanying plated patterns 32 and all the supporting patterns ST in the present disclosure to the area of the third peripheral area SA₃ is below 50%, for example, in a range from 30% to 50%.

In some implementations, in the chip on film provided in the embodiment of the present disclosure, as shown in FIGS. 7 to 10, the third peripheral area SA₃includes a first edge area SA₃₁ adjacent to the first bonding sub-area BA₃₁, and a second edge area SA₃₂ adjacent to the second bonding sub-area BA₃₂. The chip on film further includes at least two groups of common lines, each group of common lines includes a first common line CL1 and a second common line CL₂, where the first common line CL1 of each group of common lines extends in the first edge area SA₃₁ after being led out from the second bonding sub-area BA₃₂, and the second common line CL2 of each group of common lines extends in the second edge area SA₃₂ after being led out from the second bonding sub-area BA₃₂; in order to ensure uniform thicknesses of the pads 102 at both sides of the third peripheral area SA₃, in a pattern set formed by the supporting patterns ST and the second accompanying plated patterns 32, the patterns, i.e., the supporting patterns ST and the second accompanying plated patterns 32 are uniformly distributed in an area between the groups of common lines and an area between the first common line CLI and the second common line CL2 in each group of common lines.

In some implementations, in the chip on film provided in the embodiment of the present disclosure, as shown in FIGS. 7 to 10, in order to facilitate uniform arrangement of the pattern set formed by the supporting patterns ST and the second accompanying plated patterns 32, each of a plurality of supporting patterns ST and a corresponding one of a part of the second accompanying plated patterns 32 may be formed into one piece (formed into an unitary structure), and in some implementations, in a direction X intersecting the extending direction (the Y direction) in which the pads 102 extend, a width of the supporting pattern ST is substantially the same as a width of the second accompanying plated pattern 32 (i.e., the width of the supporting pattern ST is the same as the width of the second accompanying plated pattern 32, or a difference, caused by a manufacturing process, measurement error, and the like, between the width of the supporting pattern ST and the width of the second accompanying plated pattern 32 is within an error range).

In some implementations, in the chip on film provided by the embodiment of the present disclosure, as shown in FIGS. 7 to 10, in each combined pattern formed by the supporting patterns ST and the second accompanying plated pattern 32 which are formed into one piece, the supporting patterns ST may be symmetrical with respect to a central axis of the combined pattern extending in the direction X intersecting the extending direction (the Y direction) in which the pad 102 extends. That is, in the extending direction (the Y direction) in which the pad 102 extends, both ends of the supporting pattern ST may be provided with the second accompanying plated pattern 32 which is formed into one piece with the supporting pattern ST, which is advantageous for the supporting patterns ST to support the driver chip IC more uniformly.

In some implementations, in the chip on film provided in the embodiment of the present disclosure, as shown in FIGS. 7 and 8, the second accompanying plated patterns 32 disposed separately from the supporting patterns ST are independent patterns, and the combined patterns (each being composed of the supporting patterns ST and the second accompanying plated pattern 32 formed into one piece) are uniformly distributed in an area between the groups of common lines and an area between the first common line CL1 and the second common line CL2 in each group of common lines. In some implementations, independent patterns are disposed between any two adjacent combined patterns. The separate accompanying plated patterns may be substantially equally spaced between any two adjacent combined patterns, and in some implementations, a ratio of an area of the independent pattern to an area of a region between any two adjacent combined patterns ranges from 30% to 50%, such as 30%, 40%, 50%.

It should be noted that “being uniformly distributed” in the present disclosure may be understood as “being distributed at a substantially equal interval”, that is, the pitch between any two adjacent patterns is the same or a difference, caused by a manufacturing process, measurement error, and the like, between pitches between any two adjacent patterns is within an error range.

In some implementations, in order to ensure the ratio of areas of the plurality of supporting patterns ST and the plurality of second accompanying plated patterns 32 to the area of the third peripheral area SA₃, the combined patterns (each being composed of the supporting patterns ST and the second accompanying plated pattern 32 corresponding to each other that are formed into one piece) and the independent patterns (the second accompanying plated patterns 32 disposed separately from the supporting patterns ST) each may have a length, in the extending direction (the Y direction) in which the pads 102 extend, more than 50%, such as 50%, 60%, 70%, 80%, 90%, of a distance between the first common line CL₁ and the second common line CL₂.

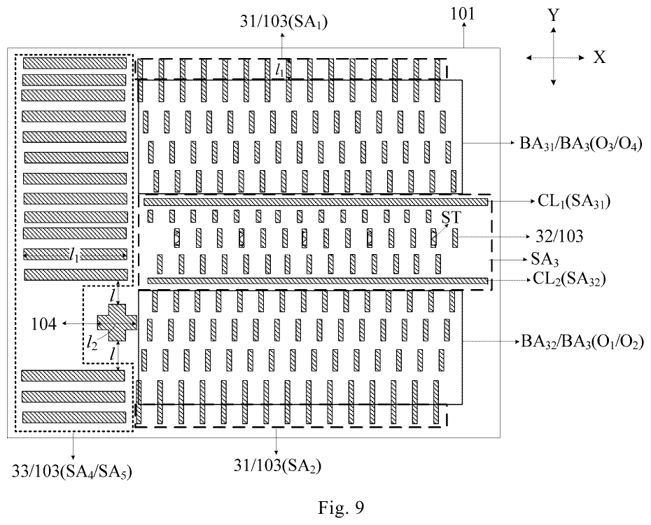

In some implementations, in the chip on film provided by the embodiment of the present disclosure, as shown in FIG. 9, the combined patterns (each being composed of the supporting pattern ST and the second accompanying plated pattern 32 that are formed into one piece) are arranged in at least one row, the independent patterns (the second accompanying plated patterns 32 that are spaced apart from the supporting pattern ST) are arranged in at least two rows, the at least one row of combined patterns and the at least two rows of independent patterns are arranged in the extending direction (the Y direction) in which the pads 102 extend, and the row of combined patterns is farther away from the first edge area SA₃₁ and the second edge area SA₃₂ than the rows of independent patterns, for example, the combined patterns each being composed of the supporting pattern ST and the second accompanying plated pattern 32 may be uniformly disposed in a middle area located in the third peripheral area SA₃, so as to uniformly support the driver chip IC through the supporting pattern ST. In some implementations, a part of the first common ling CL1 and a part of the second common line CL2 may also be used for supporting the driver chip IC.

In some implementations, in the above-described chip on film provided in the embodiment of the present disclosure, as shown in FIG. 9, in order to improve etching uniformity, a shape and the width (i.e., a dimension in the X direction intersecting with the extending direction (the Y direction) in which the pads 102 extend) of each combined pattern (composed of the supporting pattern ST and the second accompanying plated pattern 32 that are integrally formed into one piece) and a shape and the width of each independent pattern (the second accompanying plated pattern 32 that is spaced apart from the supporting pattern ST) may be substantially the same as those of the pad 102 (i.e., the shapes of the combined pattern and the independent pattern are the same as or similar to the shape of the pad 102, and the widths of the combined pattern and the independent pattern and the width of the pad 102 are the same or a difference, caused by manufacturing process, measurement error, and the like, therebetween is within an error range). Alternatively, a height (also referred to as a thickness) and a length (i.e., a dimension in the extending direction (the Y direction) in which the pad 102 extends) of the combined pattern, and a height and a length (i.e., a dimension in the extending direction (the Y direction) in which the pad 102 extends) of the independent pattern may be substantially the same as a height and a length (i.e., a dimension in the extending direction (the Y direction) in which the pad 102 extends) of the pad 102, respectively (i.e., they are the same or a difference, caused by manufacturing process, measurement error, and the like, therebetween is within an error range). Alternatively, a chip Bump (IC Bump) may be provided on a side of the supporting pattern ST away from the base substrate.

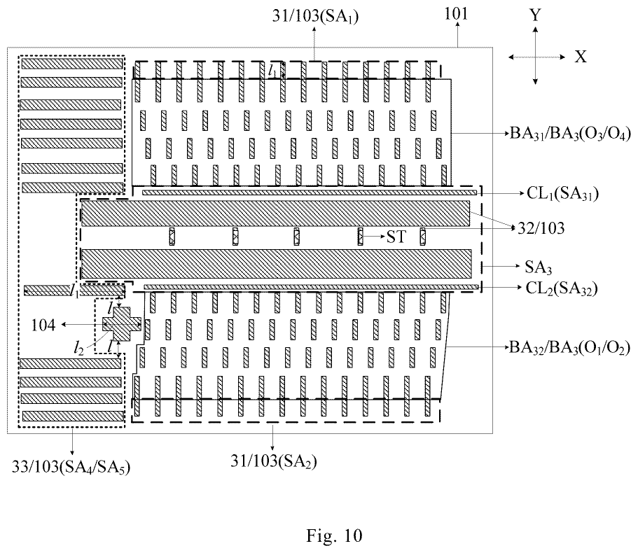

In some implementations, in the above-described chip on film provided by the embodiment of the present disclosure, as shown in FIG. 10, the combined patterns (each being composed of the supporting pattern ST and the second accompanying plated pattern 32 that are formed into one piece) are arranged in at least one row, the independent patterns (the second accompanying plated patterns 32 spaced apart from the supporting patterns ST) are strip-shaped accompanying plated patterns respectively located between an area where the combined patterns are located and the first bonding sub-area BA₃₁, and between an area where the combined patterns are located and the second bonding sub-area BA₃₂, alternatively, a length, in the direction X intersecting with the extending direction Y in which the pads 102 extend, of the strip-shaped accompanying plated pattern 32 is greater than or equal to a distance between a starting position (i.e., the first pad 102) and an ending position (i.e., the last pad 102) of each row of pads 102. In some implementations, the length, in the direction X intersecting with the extending direction Y in which the pads 102 extend, of the strip-shaped accompanying plated pattern may be greater than a length of the driver chip IC in the X direction.

In some implementations, in the above-described chip on film provided by the embodiment of the present disclosure, as shown in FIG. 6, FIG. 7, FIG. 9 and FIG. 10, the peripheral area may further include a fourth peripheral area SA₄ and a fifth peripheral area SA₅, the fourth peripheral area SA₄ and the fifth peripheral area SA₅ respectively extend in the extending direction (the Y direction) in which the pads 102 extend, and the fourth peripheral area SA₄ and the fifth peripheral area SA₅ are respectively located at two sides of the bonding area (e.g., the first bonding area BA₁, the second bonding area BA₂, and the third bonding area BA₃) in the X direction intersecting the extending direction Y in which the pads 102 extend. The chip on film may further include alignment marks 104 located in the fourth peripheral area SA₄ and the fifth peripheral area SA₅, where the alignment marks 104 are disposed in the same layer and made of a same material as the pads 102. The at least one accompanying plated pattern 103 includes a third accompanying plated pattern 33 located in the fourth peripheral area SA₄ and/or the fifth peripheral area SA₅, the third accompanying plated pattern 33 is disposed around the alignment mark 104 on at least one of edges of the alignment mark 104 at two sides of the alignment mark 104 in the extending direction (the Y direction) in which the pads 102 extend and one edge of the alignment mark 104 at a side of the alignment mark 104 away from the bonding area, and the third accompanying plated pattern 33 is spaced apart from the alignment mark 104 by a preset distance/(e.g., 0.3 mm).

In the related art, during the electroplating process, since the power lines are concentrated and the current density is great in the edge area of the bonding areas (for example, the first bonding area BA₁, the second bonding area BA₂, and the third bonding area BA₃) adjacent to the fourth peripheral area SA₄ and/or the fifth peripheral area SA₅, the thickness uniformity of the pad 102 in the edge area is poor. The third accompanying plated pattern 33 is provided in the fourth peripheral area SA₄ and/or the fifth peripheral area SA₅, so that an area where the power lines are concentrated and the current density is great is transferred to the fourth peripheral area SA₄ and/or the fifth peripheral area SA₅, therefore, the power lines are not concentrated and the current density is normal in the edge area of the bonding area (for example, the first bonding area BA₁, the second bonding area BA₂, and the third bonding area BA₃) adjacent to the fourth peripheral area SA₄ and/or the fifth peripheral area SA₅, thus the pads 102 with uniform thickness can be formed. In addition, the third accompanying plated pattern 33 is spaced apart from the alignment mark 104 by a preset distance (for example, 0.3 mm), so that the third accompanying plated pattern 33 and the alignment mark 104 are independent from each other, the alignment mark 104 can be conveniently identified in the subsequent bonding process, and the bonding yield can be improved. Alternatively, the third accompanying plated pattern 33 is not loaded with any electric signal.

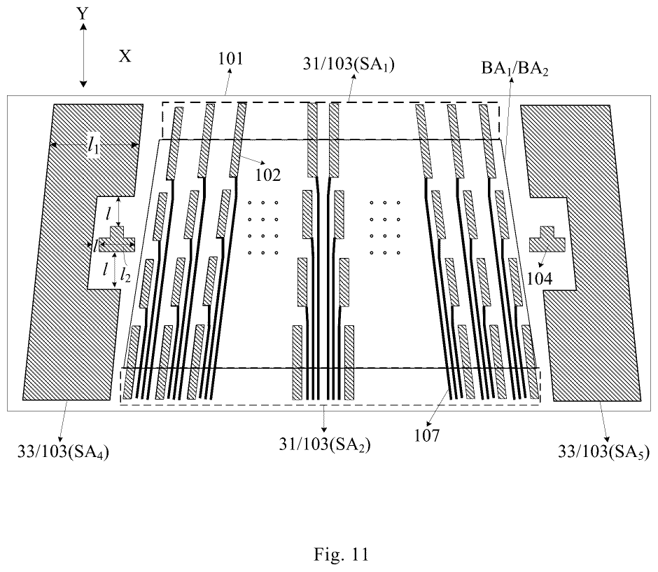

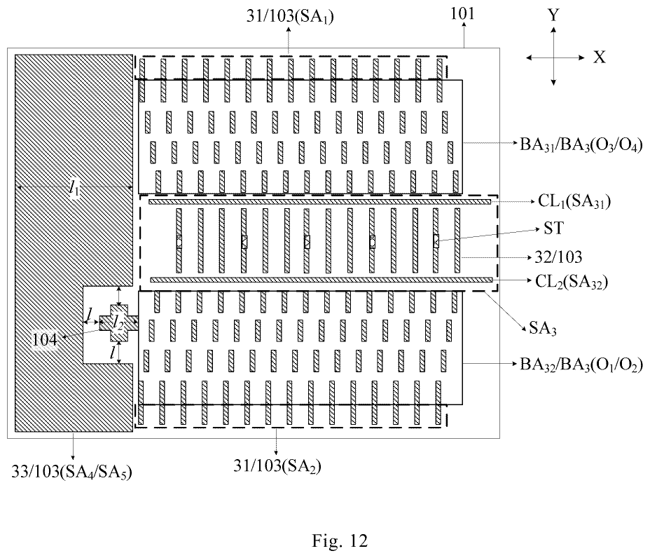

In some implementations, in the above-described chip on film provided in the embodiment of the present disclosure, as shown in FIGS. 6, 7, 9 and 10, the third accompanying plated pattern 33 may include a plurality of strip-shaped patterns sequentially arranged in the extending direction (the Y direction) in which the pads 102 extend; alternatively, as shown in FIGS. 11 and 12, the third accompanying plated pattern 33 may be a block-shaped pattern. Alternatively, in order for the pads 102 in the bonding area (e.g., the first bonding area BA₁, the second bonding area BA₂, the third bonding area BA₃) completely avoiding the area where the power lines are concentrated and the current density is great, the third accompanying plated pattern 33 may be disposed in an area, with a distance of 1 mm to 5 mm from the bonding area (e.g., the first bonding area BA₁, the second bonding area BA₂, the third bonding area BA₃), of the fourth peripheral area SA₄ and/or the fifth peripheral area SA₅, that is, the third accompanying plated pattern 33 may be disposed on both sides of the alignment mark 104 in the X direction intersecting the extending direction (the Y direction) in which the pads 102 extend, a length l₁ of the third accompanying plated pattern 33 in the X direction is greater than or equal to 1 mm and less than or equal to 5 mm, for example, 1 mm, 2 mm, 3 mm, 4 mm, 5 mm, and the like. Accordingly, on a side of the alignment mark 104 away from the bonding area (e.g., the first bonding area BA₁, the second bonding area BA₂, the third bonding area BA₃), a length of the third accompanying plated pattern 33 in the X direction is approximately equal to (l₁-l₂-l), where l₂ is a length of the alignment mark 104 in the X direction, and l is a preset distance between the alignment mark 104 and the third accompanying plated pattern 33 in the X direction.

In some implementations, in the above-described chip on film provided in the embodiment of the present disclosure, as shown in FIG. 6, FIG. 7, FIG. 9 to FIG. 12, in the extending direction (the Y direction) in which the pads 102 extend, a distance from an end surface of the third accompanying plated pattern 33 away from the bonding area (e.g., the first bonding area BA₁, the second bonding area BA₂, the third bonding area BA₃) to the bonding area (e.g., the first bonding area BA₁, the second bonding area BA₂, the third bonding area BA₃) is substantially the same as the length of the first accompanying plated pattern 31, that is, they are the same or a difference, caused by manufacturing process, measurement error, and the like, therebetween is within an error range.

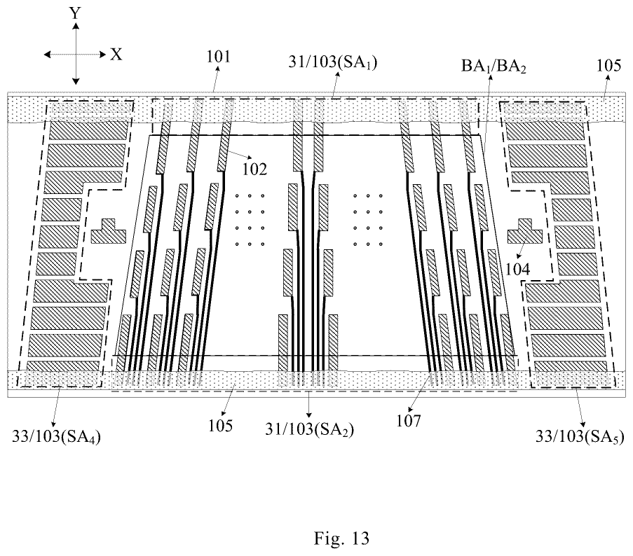

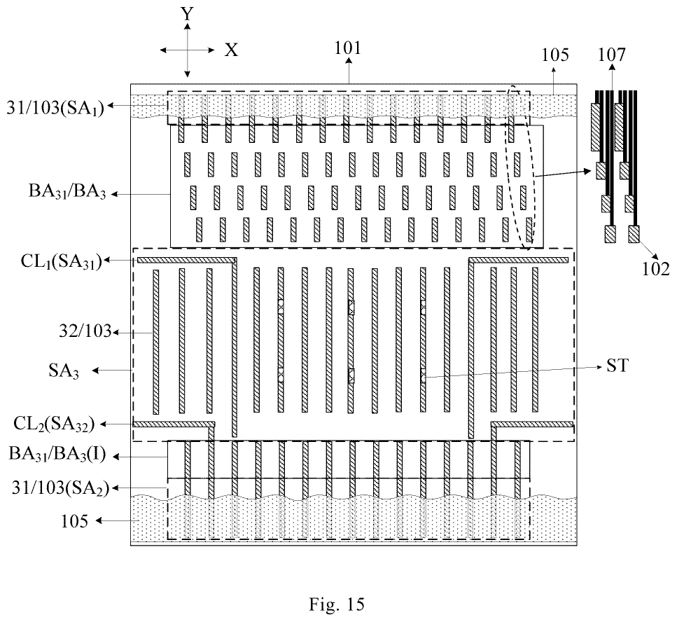

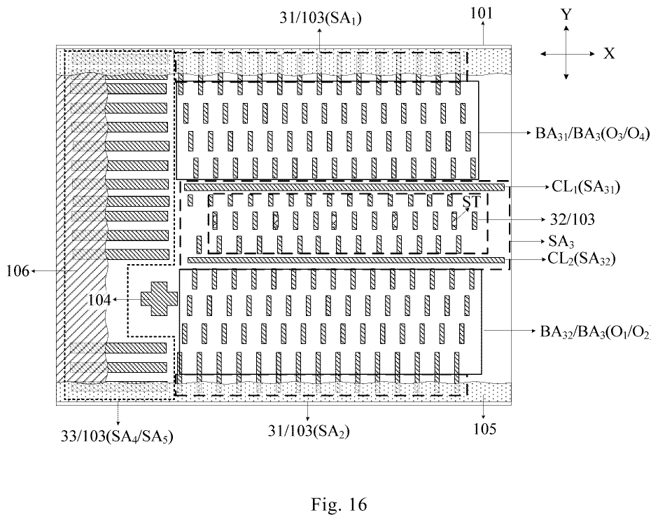

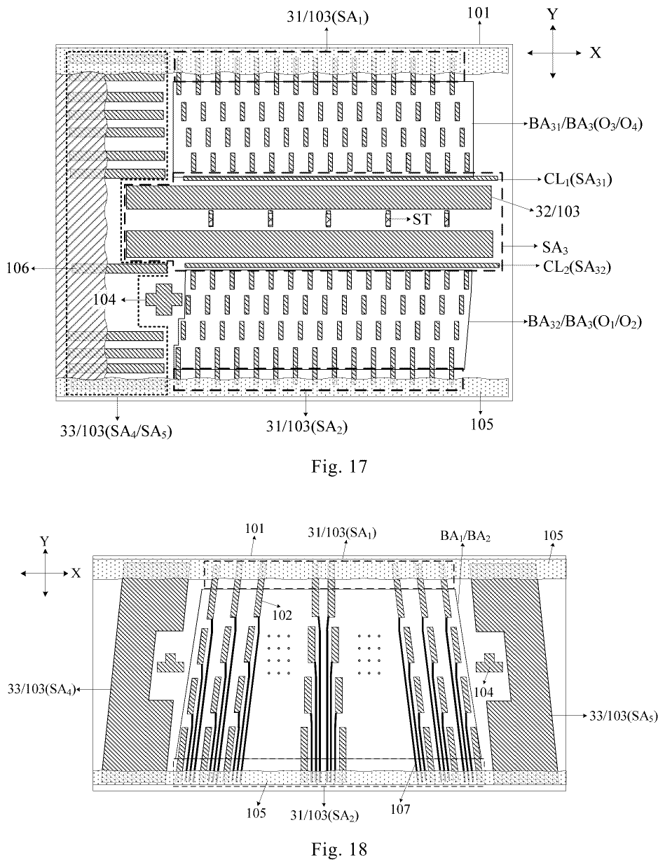

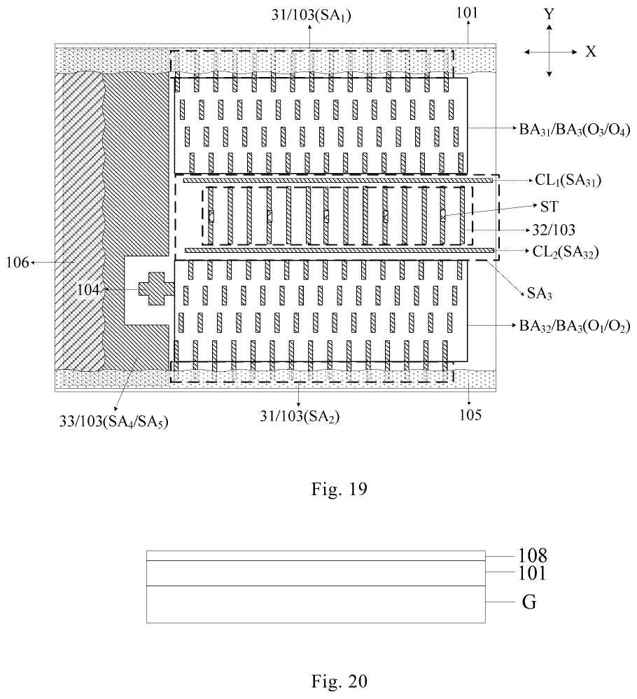

In some implementations, as shown in FIGS. 13 to 19, the above-described chip on film provided in the embodiment of the present disclosure may further include a first protective pattern 105 located on a side of a layer where the plurality of pads 102 are located, an orthographic projection of the first protective pattern 105 on the base substrate 101 overlaps orthographic projections of the first accompanying plated pattern 31 and the third accompanying plated pattern 33, which are arranged side by side in the X direction intersecting the extending direction (the Y direction) in which the pads 102 extend, on the base substrate 101, and a preset distance (for example, a preset distance of 100 μm), in the extending direction (the Y direction) in which the pads 102 extend, is provided between the orthographic projection of the first protective pattern 105 on the base substrate 101 and the bonding area (for example, the first bonding area BA₁, the second bonding area BA₂, and the third bonding area BA₃). The first protective pattern 105 can improve the flatness of a region, where the first and third accompanying plated patterns 31 and 33 are located, covered by the first protective pattern; in consideration of the manufacturing accuracy of the first protective pattern 105 and the requirement for an space for overflow of an anisotropic conductive Adhesive (ACF) in the process of subsequently bonding a display substrate to the chip on film by using the anisotropic conductive adhesive, in the present disclosure, the preset distance is provided between the first protective pattern 105 and the bonding area (e.g., the first bonding area BA₁, the second bonding area BA₂, and the third bonding area BA₃), so that the first protective pattern 105 only covers a partial area of the first accompanying plated pattern 31 away from the bonding area (e.g., the first bonding area BA₁, the second bonding area BA₂, and the third bonding area BA₃), and a partial area of the third accompanying plated pattern 33 arranged side by side with the partial area of the first accompanying plated pattern 31. In some implementations, the first protective pattern 105 may be disposed in the same layer and made of a same material as a solder resist layer in the related art, and in some implementations, the material of the first protective pattern 105 is green oil (SR) and has a thickness ranging from 5 μm to 20 μm, for example, 5 μm, 10 μm, 15 μm, 20 μm, and the like.

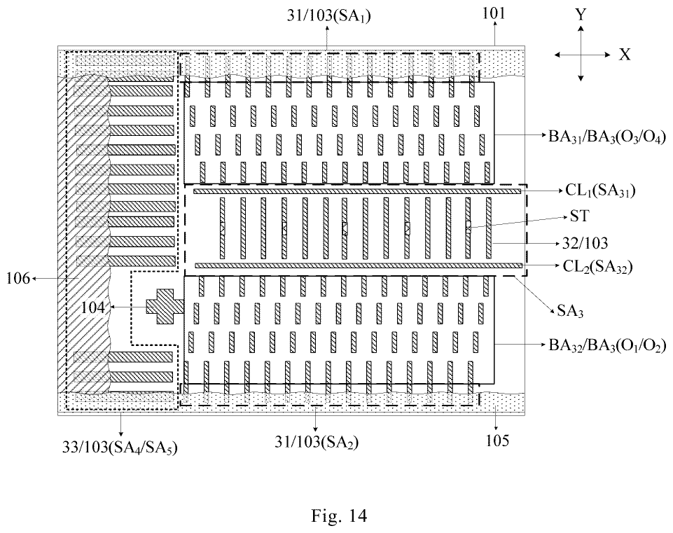

In some implementations, as shown in FIGS. 14, 16, 17, and 19, the above-described chip on film provided in the embodiment of the present disclosure further includes a second protective pattern 106, the second protective pattern 106 and the first protective pattern 105 are formed into one piece, an orthographic projection of the second protective pattern 106 on the base substrate 101 and the orthographic projection of the third accompanying plated pattern 33 on the base substrate 101 overlap each other, and in the X direction intersecting with the extending direction (the Y direction) in which the pads 102 extend, the orthographic projection of the second protective pattern 106 on the base substrate 101 has a preset distance (e.g., ranging from 100 μm to 200 μm) from the bonding area (e.g., the third bonding area BA₃). The second protective pattern 106 can improve the flatness of a region, where the third accompanying plated pattern 33 is located, covered by the second protective pattern 106; and in consideration of the manufacturing accuracy of the second protective pattern 106, in order to prevent the second protective pattern 106 from covering the pads 102, in the present disclosure, the second protective pattern 106 is provided to be spaced apart form the bonding area (e.g., the third bonding area BA₃) by a preset distance, so that the second protective pattern 106 covers only a partial area of the third accompanying plated pattern 33 away from the bonding area (e.g., the third bonding area BA₃).

In some implementations, in the above-described chip on film provided by the embodiment of the present disclosure, the plurality of bonding areas may include a first bonding area BA₁ for bonding a display substrate and a second bonding area BA₂ for bonding a flexible circuit board. Since a size, in the X direction intersecting the extending direction (the Y direction) in which the pads 102 extend, of a bonding head used in the process of bonding the display substrate and the flexible circuit board is larger than a size of the bonding area (e.g., the first bonding area BA₁ and the second bonding area BA₂), so that the bonding head may simultaneously press the bonding area (e.g., the first bonding area BA₁, the second bonding area BA₂), and the fourth peripheral area SA₄ and the fifth peripheral area SA₅, if the second protective pattern 106 covering the third accompanying plated pattern 33 is disposed in the fourth peripheral area SA₄ and the fifth peripheral area SA₅, then a height of films in the fourth peripheral area SA₄ and the fifth peripheral area SA₅ is larger than a height of films in the bonding area (e.g., the first bonding area BA₁, the second bonding area BA₂), so that the bonding area (e.g., the first bonding area BA₁, the second bonding area BA₂) cannot be uniformly stressed. In view of above, only the first protective pattern 105 may be disposed around the first and second bonding areas BA₁ and BA₂.

In some implementations, the plurality of bonding areas may further include a third bonding area BA₃ for bonding a driver chip IC, and since a size of the driver chip IC is approximately equal to a sum of a size of the third bonding area BA₃ and a size of the third peripheral area SA₃, a height of film layers in the peripheral area (e.g., the first peripheral area SA₁, the second peripheral area SA₂, the fourth peripheral area SA₄, and the fifth peripheral area SA₅) around the third bonding area BA₃ has no influence on the bonding of the driver chip IC, and thus the first protective pattern 105 and the second protective pattern 106 may be simultaneously disposed around the third bonding area BA₃.

In some implementations, in the above-described chip on film provided in the embodiment of the present disclosure, as shown in FIG. 13 and FIG. 18, in the first bonding area BA₁ and the second bonding area BA₂, rows of pads 102 are arranged at an equal interval in the extending direction (the Y direction) in which the pads 102 extend, and two adjacent rows of pads 102 are arranged in a partially staggered manner in the X direction intersecting the extending direction (the Y direction) in which the pads 102 extend. Compared with the solution that rows of pads 102 are arranged in a flush manner, the partially staggered arrangement of any two adjacent rows of pads 102 in the X direction is beneficial to ensuring a large space for arranging leads 107 electrically connected with the pads 102 in different rows.

In some implementations, in the above-described chip on film provided in the embodiment of the present disclosure, as shown in FIGS. 14 to 17 and 19, the third bonding area BA₃ includes a first bonding sub-area BA₃₁ and a second bonding sub-area BA₃₂, and in the first bonding sub-area BA₃₁ and the second bonding sub-area BA₃₂, rows of pads 102 are arranged at an equal interval in the extending direction (the Y direction) in which the pads 102 extend, and the pads 102 in two adjacent rows are arranged in a partially staggered manner in the X direction intersecting the extending direction (the Y direction) in which the pads 102 extend; in the X direction intersecting the extending direction (the Y direction) in which the pads 102 extend, the second bonding sub-area BA₃₂ includes a first signal output area O₁ and a second signal output area O₂ arranged side by side, and a signal input bonding area I located between the first signal output area O₁ and the second signal output area O₂; the first bonding sub-area BA₃₁ includes a third signal output area O₃ and a fourth signal output area O₄, the third signal output area O₃ and the first signal output area O₁ are arranged side by side in the extending direction (the Y direction) in which the pads 102 extend, and the fourth signal output area O₄ and the second signal output area O₂ are arranged side by side in the extending direction (the Y direction) in which the pads 102 extend. Alternatively, the rows of pads 102 in the first signal output area O₁ and the rows of pads 102 in the third signal output area O₃ are arranged symmetrically with respect to a central axis of the driver chip IC in the X direction intersecting the extending direction (the Y direction) in which the pads 102 extend, and the rows of pads 102 in the second signal output area O₂ and the rows of pads 102 in the fourth signal output area O₄ are arranged symmetrically with respect to the central axis of the driver chip IC in the X direction intersecting the extending direction (the Y direction) in which the pads 102 extend. Alternatively, in the present disclosure, the pads 102 in the first signal output area O₁, the second signal output area O₂, the third signal output area O₃, and the fourth signal output area O₄ are connected to source pins of the display substrate through leads 107 arranged on both sides of the driver chip IC, respectively, so as to maximize the number of the source pins; the pads 102 in the signal input bonding area I are connected to the flexible circuit board through leads 107 to receive driving signals provided from the flexible circuit board.

Correspondingly, an embodiment of the disclosure also provides a method for manufacturing a chip on film, which may comprise the following eight steps.

In a first step, as shown in FIG. 20, a base substrate 101 is coated or attached onto a glass substrate G, and a barrier layer 108 is deposited on the base substrate 101; the base substrate 101 may be a flexible substrate made of polyimide or the like, and a thickness of the base substrate 101 may be greater than or equal to 10 μμm and less than or equal to 40 μm, for example, the thickness of the base substrate 101 is 10 μm, 20 μm, 30 μm, 40 μm, or the like; a material of the barrier layer 108 may be silicon oxide (SiO₂), silicon nitride (SiN), silicon oxynitride (SiON), or the like, the barrier layer 108 may have a single-layer structure or a stacked structure, a thickness of the barrier layer 108 is greater than or equal to 100 nm and less than or equal to 500 nm, and the thickness of the barrier layer 108 is, for example, 100 nm, 200 nm, 300 nm, 400 nm, 500 nm, or the like.

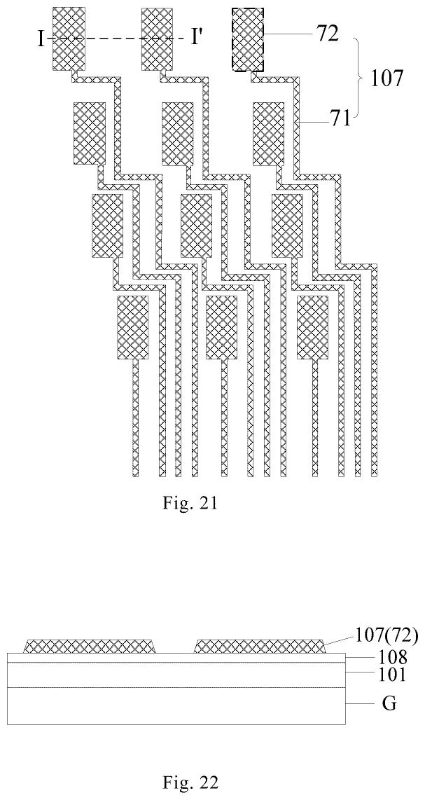

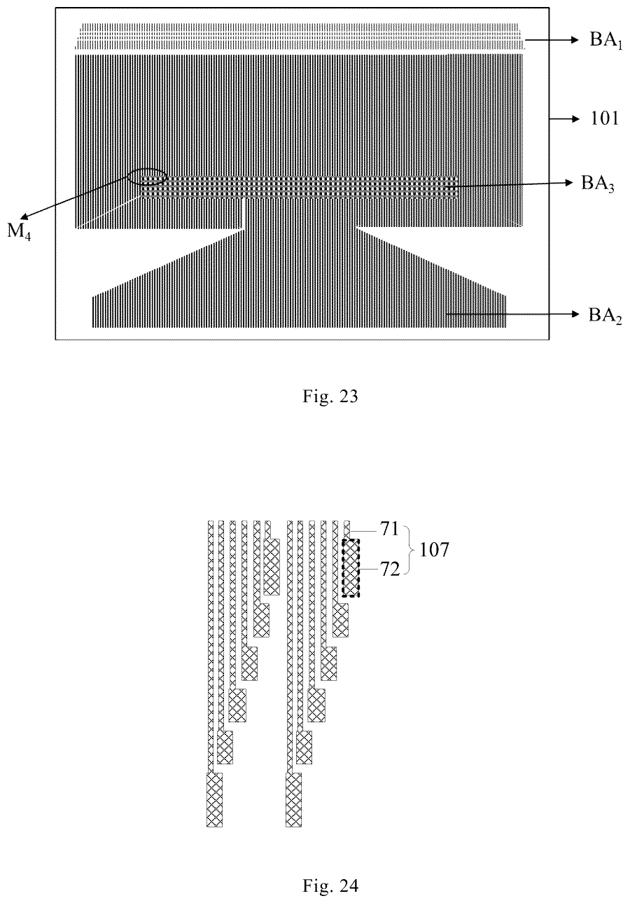

In a second step, as shown in FIGS. 21 to 24, a metal film layer is deposited on the barrier layer 108, where the metal film layer may be made of a material suitable for dry etching, such as molybdenum (Mo), aluminum (Al), titanium (Ti), and the like. The metal film layer may be a single-layer metal or a stacked metal, and the metal film layer is exemplarily of a tri-layer structure composed of titanium layer/aluminum layer/titanium layer. Alternatively, a thickness of the metal film layer made of titanium layer/aluminum layer/titanium layer is greater than or equal to 500 nm and less than or equal to 1000 nm, for example, the thickness of the metal film layer is 500 nm, 600 nm, 700 nm, 800 nm, 900 nm, 1000 nm, or the like; then the metal film layer is patterned to form leads 107, and in order to realize a smaller pitch between leads, the metal film layer is etched by using a dry etching process to form the leads 107, where each lead 107 includes a wire part 71 and a widened part 72 to be connected with a pad 102; a pitch between the widened parts 72 is required to be larger than 20 μm due to a precision limitation of a bonding equipment, and if the leads 107 are provided in a single layer, the pitch between the two adjacent wire parts 71 in an area, in which a density of the wire parts is the largest, between the widened parts 72 is less than 4 μm; in order to maximize the number of the source pins, the connection data lines are arranged at both an upper end and a lower end of the third bonding area BA₃ for bonding the driver IC, and leads 702 in a middle area at the lower end of the third bonding area BA₃ are input lines for connecting the flexible circuit board.

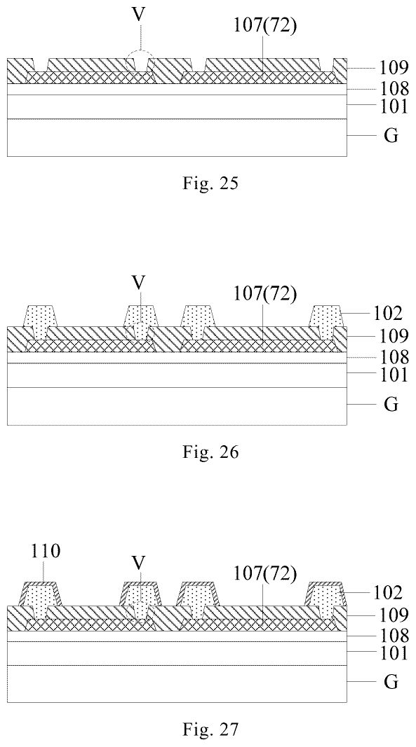

In a third step, as shown in FIG. 25, an insulating layer 109 is formed on a layer where the leads 107 are located, the insulating layer 109 may be made of silicon oxide (SiO₂), silicon nitride (SiN), silicon oxynitride (SiON), or the like, the insulating layer 109 may be a single-layer structure or a stacked structure, a thickness of the insulating layer 109 is greater than or equal to 100 nm and less than or equal to 500 nm, for example, the thickness of the insulating layer 109 is 100 nm, 200 nm, 300 nm, 400 nm, 500 nm, or the like, and a portion of the insulating layer 109 at each widened part 72 is provided with a via hole (transfer hole) V. Alternatively, each widened part 72 is electrically connected to one of pads 102 to be manufactured subsequently through at least one via hole V.

In a fourth step, as shown in FIG. 26, the pads 102 are formed on the insulating layer 109 by electroplating, a material of the pads 102 is copper, and in order to ensure sufficient space for glue overflow in the bonding process, a thickness of each pad 102 is to be greater than or equal to 5 μm and less than or equal to 8 μm, for example, the thickness of each pad 102 is 5 μm, 6 μm, 7 μm, 8 μm, or the like. It should be noted that a accompanying plated pattern 103 and a alignment mark 104 are formed simultaneously with the pads 102, and the description of the accompanying plated pattern 103 and the alignment mark 104 may refer to above and is not repeated herein.

In a fifth step, as shown in FIG. 27, an oxidation preventing layer 110 is formed on the pads 102, where a material of the oxidation preventing layer 110 may be tin (Sn) or the like, and in some implementations, the oxidation preventing layer 110 may be formed by a chemical plating process, and a thickness of the oxidation preventing layer 110 is greater than or equal to 0.5 μm and less than or equal to 2 μm, such as 0.5 μm, 1 μm, 1.5 μm, 2μm, or the like; in addition, indium tin oxide (ITO) may be coated on a surface of each pad 102 to prevent the pad 102 from being oxidized.

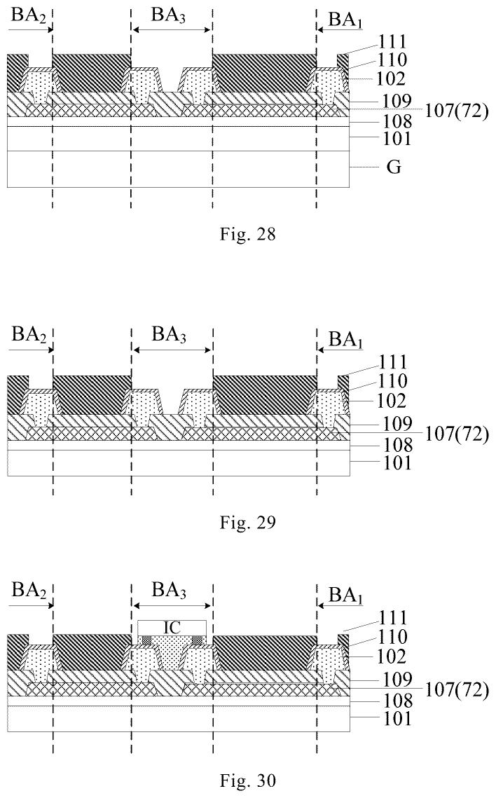

In a sixth step, as shown in FIG. 28, a solder resist layer 111 is brushed on an un-bonding area above the oxidation preventing layer 110, where a material of the solder resist layer 111 may be green oil, a thickness of the solder resist layer 111 may be greater than or equal to 5 μm and less than or equal to 20 μm. Alternatively, the thickness of the solder resist layer 111 is 5 μm, 10 μm, 15 μm, 20 μm, or the like. It should be noted that, while the solder resist layer 111 is formed, a first protective pattern 105 and a second protective pattern 106 partially covering the accompanying plated pattern 103 may also be formed near the bonding area (for example, a first bonding area BA₁, a second bonding area BA₂, and a third bonding area BA₃), and the description of the accompanying plated pattern 103 and the alignment mark 104 may refer to those as stated above and is not repeated herein.

In a seventh step, as shown in FIG. 29, the above large-sized chip on film is subjected to a laser lift-off (LLO) process to remove the glass substrate G, and then is cut to obtain a plurality of chip on films each with a target size.

In an eighth step, as shown in FIG. 30, the chip on film with the target size is bonded to a driver IC in the third bonding area BA₃ for bonding the driver IC, and a dispensing packaging process is performed to obtain the chip on film with the driver IC.

It should be noted that, in the method for manufacturing the chip on film provided in the embodiment of the present disclosure, the patterning process related to forming each layer structure may include not only some or all of the processes such as deposition, photoresist coating, masking with a mask, exposure, development, etching, and photoresist stripping, but also other processes, which can be specifically determined based on a pattern to be formed in an actual manufacturing process, which is not limited herein. For example, a post-bake process may be further included after development and before etching.

The deposition process may be a chemical vapor deposition method, a plasma enhanced chemical vapor deposition method, or a physical vapor deposition method, which is not limited herein; the mask used in the masking process may be a half tone mask, a single slit diffraction mask (also referred as Single Slit Mask) or a gray tone mask, which is not limited herein; the etching may be dry etching or wet etching, and is not limited herein.

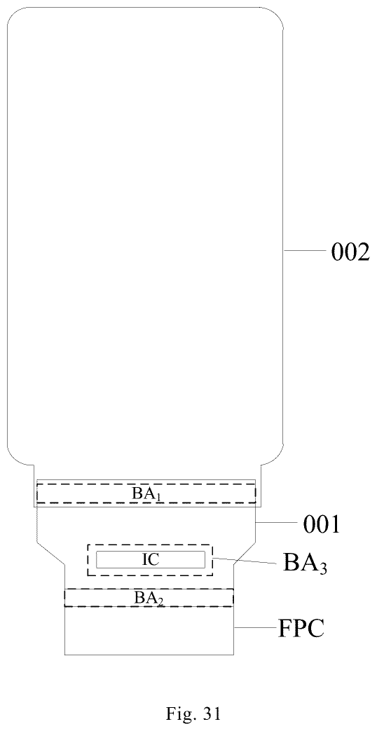

Based on the same inventive concept, an embodiment of the present disclosure provides a display apparatus, as shown in FIG. 31, the display apparatus may include a chip on film 001, a display substrate 002, a driver chip IC, and a circuit board (e.g., a flexible circuit board FPC), where the chip on film 001 is the above-described chip on film 001 provided in the embodiment of the present disclosure, the chip on film 001 includes bonding areas corresponding to the display substrate 001, the driver chip IC, and the circuit board (e.g., the flexible circuit board FPC) one to one. In some implementations, the display substrate 002 is electrically connected to the first bonding area BA₁ of the chip on film 001, the flexible circuit board FPC is electrically connected to the second bonding area BA₂ of the chip on film 001, and the driver chip IC is electrically connected to the third bonding area BA₃ of the chip on film 001.

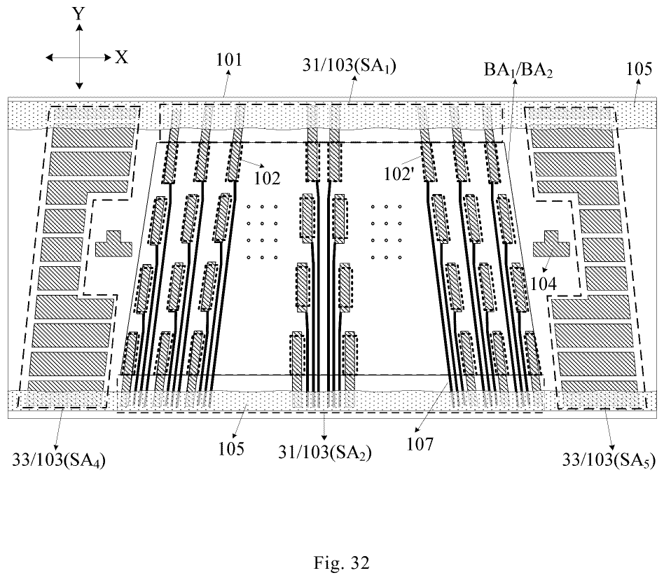

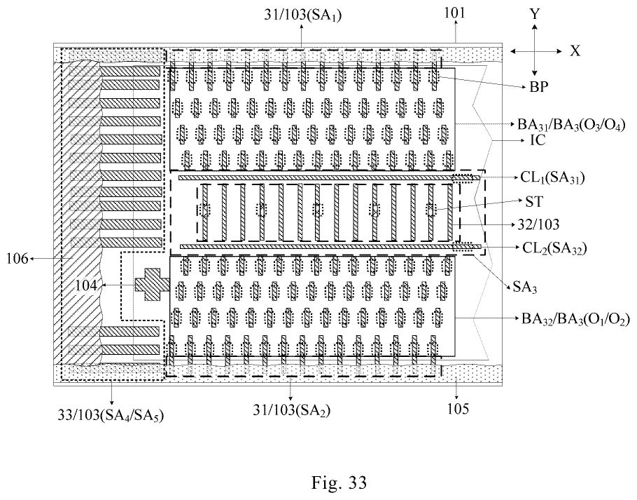

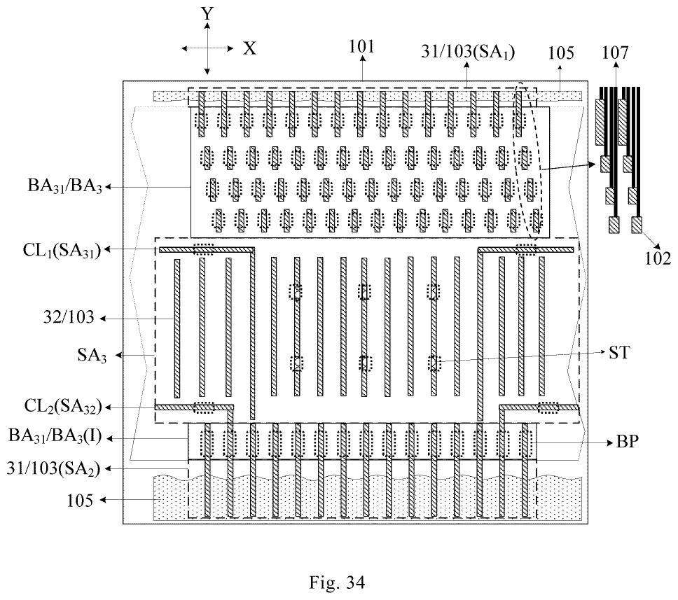

In some implementations, as shown in FIG. 32, pins 102′ of the display substrate 002 or the flexible circuit board FPC are electrically connected to the pads 102 in the corresponding bonding areas in the chip on film 001 in a one-to-one correspondence. Alternatively, as shown in FIGS. 33 and 34, the bumps BP of the driver chip IC are electrically connected to the pads 102 in the first bonding sub-area BA₃₁ and the second bonding sub-area BA₃₂ one to one, and in the third peripheral area SA₃ between the first bonding sub-area BA₃₁ and the second bonding sub-area BA₃₂, supporting patterns ST fixedly connected to the bumps BP of the driver chip IC are uniformly arranged, and in some implementations, the bumps BP corresponding to the supporting patterns ST each do not provide an electrical signal, and only play a role of balancing the bonding pressure. Furthermore, as shown in FIGS. 33 and 34, the chip on film further includes the first common line CL₁ and the second common line CL₂, the first common line CL₁ and the second common line CL₂ may access a power signal (Pwr), a ground signal (Gnd) and the like provided by the flexible circuit board FPC, and in some implementations, the bumps BP playing a role of balancing the bonding pressure in the driver chip IC may also be fixedly connected to the common line CL.

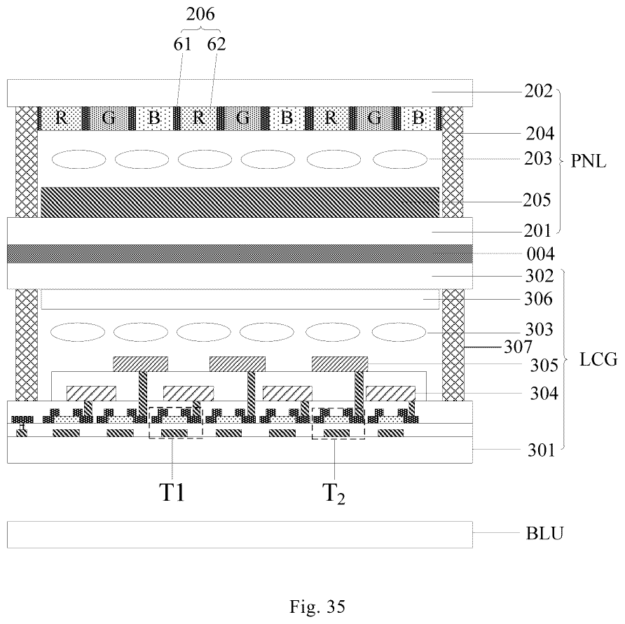

In some implementations, the display apparatus provided in the embodiment of the present disclosure may be specifically a liquid crystal display apparatus. As shown in FIG. 35, the liquid crystal display apparatus includes a backlight module BLU and a liquid crystal display panel PNL located at a light-emitting side of the backlight module BLU. The liquid crystal display panel may be a twisted nematic (TN) type liquid crystal display panel, an Advanced Dimensional Switch (ADS) type liquid crystal display panel, a High-Advanced Dimension Switch (HADS) type liquid crystal display panel, an In-Plane Switch (IPS) type liquid crystal display panel, and the like.

In some implementations, the liquid crystal display panel PNL includes a first substrate 201 and a second substrate 202 disposed opposite to each other, and a first liquid crystal layer 203 disposed between the first substrate 201 and the second substrate 202 facing each other, where a first sealant 204 surrounding the first liquid crystal layer 203 is disposed between the first substrate 201 and the second substrate 202, a driving circuit 205 and a pixel electrode (not shown) are disposed on a side of the first substrate 201 facing the first liquid crystal layer 203, a color filter layer 206 may be disposed on a side of the second substrate 202 facing the first liquid crystal layer 203, the color filter layer 206 includes a black matrix 61 and color filters 62. In some implementations, a common electrode (Com) of the liquid crystal display panel PNL may be disposed on a side, away from the first substrate 201, of a layer where the driving circuit 205 is located or on a side of the color filter layer 206 away from the second substrate 202, the liquid crystal display panel PNL may further include a first polarizer (pol, not shown) located on a side of the first substrate 201 away from the first liquid crystal layer 203, and a second polarizer (pol, not shown) located on a side of the second substrate 202 away from the first liquid crystal layer 203, a transmission axis of the first polarizer being perpendicular to a transmission axis of the second polarizer.

In some implementations, the backlight module BLU may be a direct-down type backlight module or a side-in type backlight module. In some implementations, the side-in type backlight module may include a light bar, and a reflector, a light guide plate, a diffuser, a prism group, which are stacked, and the like, where the light bar is located on a side of the light guide plate in a thickness direction of the light guide plate. The direct-down type backlight module may include a matrix light source, and a reflector plate, a diffuser plate and a brightness enhancement film which are stacked on a light-emitting side of the matrix light source, the reflector plate includes openings provided directly opposite to lamp beads in the matrix light source. Lamp beads in the lamp bar and the lamp beads in the matrix light source may be light-emitting diodes (LEDs), such as micro light-emitting diodes (Mini LED, Micro LED, and the like).

Submillimeter or even micrometer-sized micro light-emitting diodes and the organic light-emitting diodes (OLEDs) both are self-luminous devices. Like the organic light-emitting diodes, the micro light-emitting diodes each have a series of advantages of high brightness, ultralow delay, overlarge visual angle and the like. Furthermore, since an inorganic light-emitting diode emits light based on the metal semiconductor with more stable property and lower resistance, compared with the organic light-emitting diode which emits light based on organic matters, the inorganic light-emitting diode has the advantages of lower power consumption, higher high temperature resistance, low temperature resistance and longer service life. In a case where the micro light-emitting diodes serve as the backlight source, a more precise dynamic backlight effect can be achieved, brightness and contrast of the screen are effectively improved. Meanwhile, the glare phenomenon caused by the traditional dynamic backlight source between the bright and dark areas of the screen can be solved, and visual experience can be optimized.

In some implementations, the display apparatus provided in the embodiment of the present disclosure may be a three-dimensional (3D) display apparatus, and in this case, as shown in FIG. 35, the display apparatus may further include a liquid crystal grating LCG located between the backlight module BLU and the liquid crystal display panel PNL, and the liquid crystal grating LCG may be fixed to the liquid crystal display panel PNL through an adhesive layer 004. In some implementations, according to current positions of eyes of a viewer, the liquid crystal grating LCG may be controlled to form the light-transmitting areas and the light-shielding areas which are alternately arranged, so that the left eye of the viewer sees an image for the left eye displayed by the display panel PNL through the light-transmitting areas of the liquid crystal grating LCG, and the right eye of the viewer sees an image for the right eye displayed by the display panel PNL through the light-transmitting areas of the liquid crystal grating LCG. By arranging the liquid crystal grating LCG at a light incident side of the liquid crystal display panel PNL, in a case where the liquid crystal display panel PNL includes a touch electrode, the liquid crystal grating LCG cannot shield the touch electrode in the liquid crystal display panel PNL, thereby avoiding the problem of touch failure, and improving the touch sensitivity and accuracy of the liquid crystal display panel PNL.

In some implementations, as shown in FIG. 35, the liquid crystal grating LCG may include: a third substrate 301 and a fourth substrate 302 which are opposite to each other, a second liquid crystal layer 303 between the third substrate 301 and the fourth substrate 302, a first strip-shaped electrode 304 on a side of the third substrate 301 facing the second liquid crystal layer 303, a second strip-shaped electrode 305 on a side of a layer, where the first strip-shaped electrode 304 is located, facing the second liquid crystal layer 303, a planar electrode 306 on a side of the fourth substrate 302 facing the second liquid crystal layer 303, a first transistor T1 electrically connected to the first strip-shaped electrode 304, a second transistor T2 electrically connected to the second strip-shaped electrode 305, and a second encapsulation layer 307 between the third substrate 301 and the fourth substrate 302 and surrounding the second liquid crystal layer 303. In a specific implementation, by applying power to the first strip-shaped electrode 304, the second strip-shaped electrode 305, and the planar electrode 306, the second liquid crystal layer 303 may be controlled to form light-transmitting areas and light-shielding areas, so as to cooperate with the liquid crystal display panel PNL outputting the image for the left eye and the image for the right eye to implement a 3D display.

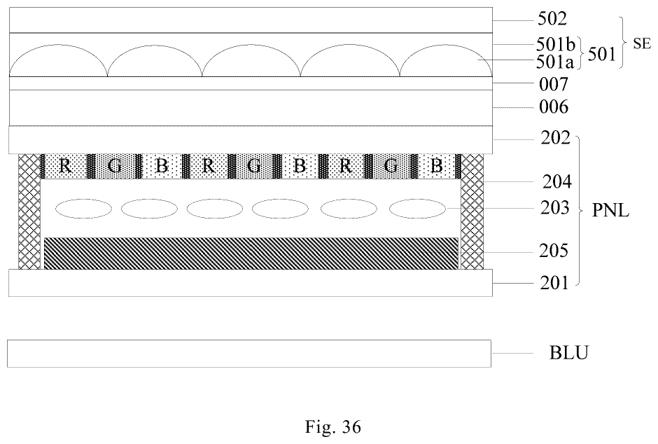

In some implementations, the display apparatus provided by the embodiment of the present disclosure may be a 3D display apparatus. As shown in FIG. 36, the 3D display apparatus may further include a light splitting assembly SE located on the light-emitting side of the liquid crystal display panel PNL. In some implementations, the light splitting assembly SE includes a plurality of light splitting structures 501 arranged parallel to each other and side by side, each light splitting structure 501 may be a composite lens formed by a high-refractive resin layer 501a and a low-refractive resin layer 501b. Specifically, the high-refractive resin layer 501a is formed by a plurality of cylindrical lenses, and the low-refractive resin layer 501b fills gaps between the cylindrical lenses and has a thickness greater than an arch height of each cylinder lens. Each cylindrical lens may be of a prism or non-prism structure. In some implementations, the light splitting assembly SE may further include a substrate 502 made of a transparent material, and the composite lens may formed on the substrate 502, and for example, the material of the substrate 502 may be polyethylene terephthalate (PET). In some implementations, a spacer glass 006 may be disposed between the liquid crystal display panel PNL and the light splitting assembly SE, and the spacer glass 006 and the light splitting assembly SE are attached and fixed to each other by an optical adhesive 007.

In a specific implementation, an image plane of the liquid crystal display panel PNL is located on a focal plane of the cylindrical lens, each pixel below each cylindrical lens is divided into a plurality of sub-pixels, pixels at different positions on the liquid crystal display panel PNL are subjected to light splitting by refraction of the cylindrical lenses, light paths are changed to form different viewpoints in space, and when a left eye receives a left viewpoint image, and a right eye receives a right viewpoint image, a 3D display is achieved.

In some implementations, the liquid crystal display panel in the display apparatus provided in the embodiment of the present disclosure may be replaced by an organic light-emitting diode (OLED) display panel, or a quantum dot light-emitting (QLED) display panel, which is not limited herein. The OLED display panel or the QLED display panel includes a light-emitting device and a pixel driving circuit electrically connected with the light-emitting device; where the light-emitting device may include a cathode and an anode which are oppositely disposed, and a light-emitting functional layer between the cathode and the anode; the pixel driving circuit may include a thin film transistor, a storage capacitor, and the like, and may be implemented in various types, for example, a 2TIC type (i.e., including two thin film transistors and one storage capacitor), and may further include more transistors and/or capacitors on the basis of the 2T1C type so as to have functions of compensation, reset, light emission control, detection, and the like, which is not limited in the embodiment of the present disclosure. For example, in some implementations, the thin film transistor directly electrically connected to the light-emitting device may be a driving transistor (Td), a light emission control transistor (EM), or the like.

In some implementations, the light-emitting functional layer includes, but is not limited to, a hole injection layer, a hole transport layer, an electron blocking layer, a light-emitting material layer, a hole blocking layer, an electron transport layer, an electron injection layer, and the like. The light-emitting material layer may be a red light-emitting material layer, a green light-emitting material layer, a blue light-emitting material layer, a yellow light-emitting material layer, a white light-emitting material layer, and the like. For the OLED display apparatus, the light-emitting material layer may include an organic material of small molecules or polymer molecules, and may be a fluorescent light-emitting material, a phosphorescent light-emitting material, or the like. For the QLED display apparatus, the light-emitting material layer may include silicon quantum dots, germanium quantum dots, cadmium sulfide quantum dots, cadmium selenide quantum dots, zinc selenide quantum dots, cadmium telluride quantum dots, lead sulfide quantum dots, lead selenide quantum dots, indium phosphide quantum dots, indium arsenide quantum dots, or the like.

In some implementations, a material of the anode may include at least one of transparent conductive oxide materials, such as indium tin oxide (ITO), indium zinc oxide (IZO), zinc oxide (ZnO); in addition, the anode may include a reflective layer made of a metal having high reflectivity, such as silver (Ag). A material of the cathode may include a metal material, such as lithium (Li), aluminum (Al), magnesium (Mg), silver (Ag).

In some implementations, the thin film transistor includes a gate electrode, a source electrode, a drain electrode, and an active layer, where a material of the active layer may include amorphous silicon, polysilicon, or an oxide semiconductor (e.g., indium gallium zinc oxide). Materials of the gate electrode, the source electrode and the drain electrode may be of a single-layer structure or a multi-layer structure made of a metal material or an alloy material, such as molybdenum, aluminum, titanium. For example, the multi-layer structure includes a plurality of metal layers (e.g., three metal layers of titanium, aluminum, and titanium (Ti/Al/Ti)) that are stacked. Alternatively, the thin film transistor may be a bottom gate transistor, a top gate transistor, a double gate transistor, or the like. In some implementations, the thin film transistor may be a P-type transistor or an N-type transistor, where the P-type transistor is turned on when a voltage difference Vgs between the gate electrode and the source electrode thereof and a threshold voltage Vth thereof satisfies a relationship Vgs<Vth, and is turned off when the voltage difference Vgs between the gate electrode and the source electrode thereof and the threshold voltage Vth thereof satisfies a relationship Vgs≤Vth, and the N-type transistor is turned on when a voltage difference Vgs between the gate electrode and the source electrode thereof and a threshold voltage Vth thereof satisfies a relationship Vgs>Vth, and is turned off when the voltage difference Vgs between the gate electrode and the source electrode thereof and the threshold voltage Vth thereof satisfies a relationship Vgs≤Vth.

In some implementations, the OLED/QLED display panel may further include an encapsulation layer on the light-emitting side of the light-emitting device. The encapsulation layer seals the light-emitting device, so that deterioration of the light-emitting device due to moisture and/or oxygen contained in the environment can be reduced or prevented. The encapsulation layer may be a single-layer structure or a composite-layer structure, and the composite-layer structure includes a structure in which an inorganic layer and an organic layer are stacked, for example, the encapsulation layer may include a first inorganic encapsulation layer, a first organic encapsulation layer, and a second inorganic encapsulation layer, which are sequentially disposed. A material of the encapsulation layer may include an insulating material such as silicon nitride, silicon oxide, silicon oxynitride, and polymer resin. Inorganic materials such as silicon nitride, silicon oxide, and silicon oxynitride have high compactness and can prevent invasion of moisture, oxygen, and the like; the organic encapsulation layer may be made of a polymer material containing a desiccant, a polymer material capable of blocking moisture such as a polymer resin, or the like, so as to planarize a surface of the display substrate, relieve stress of the first inorganic encapsulation layer and the second inorganic encapsulation layer, and the organic encapsulation layer may further include a water-absorbing material such as a desiccant to absorb substances, such as water and oxygen invading into the display panel.

In some implementations, the OLED/QLED display panel may further include a touch structure above the encapsulation layer, and the touch structure may be a self-capacitive type touch structure or a mutual capacitive type touch structure. The self-capacitive type touch structure includes a plurality of self-capacitive electrodes which are arranged in an array (in a same layer), and each self-capacitive electrode is electrically connected with a touch processing circuit (a touch driver chip) through a touch lead. Position detection is achieved by detecting a change in capacitance of the self-capacitive electrode due to, for example, a finger approaching when touching. The mutual capacitive type touch structure includes a plurality of first touch signal lines extending along a first direction and a plurality of second touch signal lines extending along a second direction, where the first touch signal lines and the second touch signal lines are electrically connected with the touch processing circuit (the touch driver chip) through touch leads. The first direction and the second direction intersect each other and form openings, so that touch capacitances are formed at intersection points of the first touch signal lines and the second touch signal lines, and position detection is achieved by detecting a change in the touch capacitances due to, for example, a finger approaching when touching. The touch structure may be formed by indium tin oxide, metal mesh, or the like.

In some implementations, the OLED/QLED display panel may further include a circular polarizer or a color filter layer on the layer where the touch structure is located, where the color filter layer includes a black matrix in a mesh shape and color filters disposed in mesh holes. In some implementations, a protective cover plate is further disposed on the circular polarizer or the color filter layer. In some implementations, the protective cover plate may be an ultra-thin glass (UTG) cover plate, and since the ultra-thin glass cover plate not only maintains the characteristics of glass, but also has good flexibility, the desirations for foldable products can be completely met. Specifically, ultra-thin glass (UTG) refers to a glass layer with a thickness of tens of microns or less that can be bent and deformed, and folded. Compared with a polymer plastic film, the ultra-thin glass can effectively avoid screen damage and can provide better optical definition; meanwhile, the ultra-thin glass is not easy to crease and thus has good reliability, and ultra-thin glass cannot be naturally decomposed like plastic, thus has long service life, thereby providing more stable and reliable protection for the display screen.

In some implementations, the display apparatus provided in the embodiments of the present disclosure may be: any product or component with a display function, such as a mobile phone, a tablet computer, a television, a display, a notebook computer, a digital photo frame, a navigator, an intelligent watch, a fitness wrist strap, and a personal digital assistant. In some implementations, the display apparatus provided in the embodiment of the present disclosure includes but is not limited to: a radio frequency unit, a network module, an audio output/input unit, a sensor, a display unit, a user input unit, an interface unit and a control chip. In some implementations, the control chip is a central processing unit, a digital signal processor, a system on chip (SoC), or the like. For example, the control chip may further include a memory, a power module, and the like, and the control chip can realize power supply and signal input/output functions through additionally provided wires, signal lines, and the like. For example, the control chip may further include hardware circuits, computer executable codes, and the like. The hardware circuits may include conventional Very Large Scale Integration (VLSI) circuits or gate arrays, and conventional semiconductors such as logic chips and transistors, or other discrete components; the hardware circuits may further include field programmable gate arrays, programmable array logic, programmable logic devices, or the like. In addition, it may be understood by those skilled in the art that the above-described structures do not constitute a limitation on the above-described display apparatus provided by the embodiment of the present disclosure. In other words, the above-described display apparatus provided by the embodiment of the present disclosure may include more or less components described above, combine some of the components described above, or have different arrangements of the components.

It will be apparent to those skilled in the art that various changes and modifications may be made in the embodiments of the present disclosure without departing from the spirit and scope of the embodiments of the present disclosure. Thus, if such changes and modifications of the embodiments of the present disclosure are within the scope of the claims of the present disclosure and their equivalents, the present disclosure is also intended to encompass such changes and modifications.

1. A chip on film, comprising:
a base substrate having a plurality of bonding areas and at least one peripheral area arranged around each bonding area;
a plurality of bonding pads located on the base substrate, wherein each bonding area is provided with multiple bonding pads; and
at least one accompanying plated pattern, which is located in a same layer and made of a same material as the plurality of bonding pads, and is located in a part of the peripheral area on at least one side of the bonding area.

2. The chip on film of claim 1, wherein in each of the bonding areas, the pads are arranged in a plurality of rows along an extending direction in which the pads extend, the at lest one peripheral area comprises a first peripheral area adjacent to a first row of pads and a second peripheral area adjacent to a last row of pads, and the at least one accompanying plated pattern comprises first accompanying plated patterns located in the first peripheral area and/or the second peripheral area.

3. The chip on film of claim 2, wherein the first accompanying plated patterns correspond to the pads in the first row and/or the pads in the last row one by one, and each first accompanying plated pattern and the pad corresponding to the first accompanying plated pattern are formed into one piece.

4. The chip on film according to claim 2, wherein one of the plurality of bonding areas comprises a first bonding sub-area and a second bonding sub-area arranged side by side in the extending direction of the pads; and
the at least one peripheral area further comprises a third peripheral area located between the first bonding sub-area and the second bonding sub-area, and the at least one accompanying plated pattern comprises a plurality of second accompanying plated patterns located in the third peripheral area.

5. The chip on film of claim 4, further comprising a plurality of supporting patterns located in the third peripheral area.

6. The chip on film of claim 5, wherein the third peripheral area comprises a first edge area adjacent to the first bonding sub-area and a second edge area adjacent to the second bonding sub-area;
the chip on film further comprises at least two groups of common lines, each group of common lines comprising a first common line and a second common line, the first common line extending in the first edge area after being led out from the second bonding sub-area, and the second common line extending in the second edge area after being led out from the second bonding sub-area; and
in a pattern set formed by the plurality of supporting patterns and the plurality of second accompanying plated patterns, the supporting patterns and the second accompanying plated patterns are uniformly distributed in an area between the groups of common lines and an area between the first common line and the second common line in each group of common lines.

7. The chip on film of claim 6, wherein each supporting pattern of the plurality of supporting patterns and one of a portion of the second accompanying plated patterns corresponding to the supporting pattern are formed into one piece, and
wherein in a combined pattern of the supporting patterns and the second accompanying plated pattern which are formed into one piece, the supporting patterns are symmetrical with respect to a central axis of the combined pattern extending in a direction intersecting the extending direction in which the pads extend.

8. (canceled)

9. The chip on film of claim 7, wherein the second accompanying plated patterns spaced apart from the supporting patterns are independent patterns, and all the combined patterns are uniformly distributed in the area between the groups of common lines and the area between the first common line and the second common line in each group of common lines, and
wherein a shape and a width of each combined pattern and a shape and a width of each independent pattern are substantially the same as a shape and a width of each pad.

10. The chip on film of claim 9, wherein in the extending direction in which the pads extend, a length of each combined pattern and a length of each independent pattern each are more than 50% of a distance between the first common line and the second common line.

11. The chip on film of claim 7, wherein the second accompanying plated patterns spaced apart from the supporting patterns are independent patterns, the combined patterns are arranged in at least one row, the independent patterns are arranged in at least two rows, the at least one row of combined patterns and the at least two rows of independent patterns are arranged in the extending direction in which the pads extend, and the row of combined patterns is farther away from the first edge area and the second edge area than the rows of independent patterns, and
wherein shape and a width of each combined pattern and a shape and a width of each independent pattern are substantially the same as a shape and a width of each pad, respectively.

12. (canceled)

13. The chip on film of claim 7, wherein the second accompanying plated patterns spaced apart from the supporting patterns are independent patterns, the combined patterns are arranged in at least one row, and the independent patterns are strip-shaped accompanying plated patterns between an area where the combined patterns are located and the first bonding sub-area, and between the area where the combined patterns are located and the second bonding sub-area; and
in the direction intersecting the extending direction in which the pads extend, a length of the strip-shaped accompanying plated pattern is larger than or equal to a distance between a first pad and a last pad of the row of pads.

14. (canceled)

15. The chip on film of claim 1, wherein the at least one peripheral area comprises a fourth peripheral area and a fifth peripheral area, the fourth peripheral area and the fifth peripheral area extend in the extending direction in which the pads extend, and in a direction intersecting the extending direction in which the pads extend, the fourth peripheral area and the fifth peripheral area are located on both sides of the bonding areas;
the chip on film further comprises alignment marks located in the fourth peripheral area and the fifth peripheral area, and the alignment marks and the pads are arranged in a same layer and made of a same material; and
the at least one accompanying plated pattern comprises at least one third accompanying plated pattern located in the fourth peripheral area and/or the fifth peripheral area, the at least one third accompanying plated pattern is arranged at two sides of the alignment mark in the extending direction in which the pads extend, surrounds at least one of edges of the alignment mark at a side of the alignment mark away from the bonding areas, and the at least one third accompanying plated pattern is spaced apart from the alignment mark by a preset distance.

16. The chip on film of claim 15, wherein the third accompanying plated pattern is a block-shaped pattern, or
the third accompanying plated pattern comprises a plurality of strip-shaped patterns sequentially arranged in the extending direction in which the pads extend.

17. (canceled)

18. The chip on film of claim 15, wherein at both sides of the alignment mark in the direction intersecting the extending direction in which the pads extend, each third accompanying plated pattern has a length greater than or equal to 1 mm and less than or equal to 5 mm in the direction intersecting the extending direction in which the pads extend.

19. The chip on film of claim 15, wherein in the direction intersecting the extending direction in which the pads extend, a distance from an end surface of the third acommpanying plated pattern away from the bonding area to the bonding area is substantially equal to a length of the first accompanying plated pattern.

20. The chip on film of claim 15, further comprising a first protective pattern on a side of a layer where the plurality of pads are located away from the base substrate, wherein an orthographic projection of the first protective pattern on the base substrate overlaps orthographic projections of the first accompanying plated pattern and the third accompanying plated pattern on the base substrate, the first accompanying plated pattern and the third accompanying plated pattern being arranged side by side in a direction intersecting the extending direction in which the pads extend, and in the extending direction in which the pads extend, the orthographic projection of the first protective pattern on the base substrate is spaced apart from each of the bonding areas by a preset distance.

21. The chip on film of claim 20, wherein the plurality of bonding areas comprise a first bonding area for bonding a display substrate and a second bonding area for bonding a circuit board, and
wherein in each of the first bonding area and the second bonding area, two adjacent rows of pads are partially staggered in a direction intersecting the extending direction in which the pads extend.

22. (canceled)

23. The chip on film of claim 20, further comprising a second protective pattern, the second protective pattern and the first protective pattern being formed into one piece, wherein an orthographic projection of the second protective pattern on the base substrate overlaps the orthographic projection of the third accompanying plated pattern on the base substrate, and in a direction intersecting the extending direction in which the pads extend, the orthographic projection of the second protective pattern on the base substrate is spaced apart from each of the bonding areas by a preset distance.

24. The chip on film of claim 23, wherein the plurality of bonding areas comprise a third bonding area for bonding a driver chip, and
wherein the third bonding area comprises a first bonding sub-area and a second bonding sub-area, and in each of the first bonding sub-area and the second bonding sub-area, two adjacent rows of pads are partially staggered in a direction intersecting an extending direction in which the pads extend;
in the direction intersecting the extending direction in which the pads extend, the second bonding sub-area comprises a first signal output area and a second signal output area which are arranged side by side, and a signal input area located between the first signal output area and the second signal output area, and
the first bonding sub-area comprises a third signal output area and a fourth signal output area, the third signal output area and the first signal output area being arranged side by side in the extending direction in which the pads extend, and the fourth signal output area and the second signal output area being arranged side by side in the extending direction in which pads extend.

25. (canceled)

26. A display apparatus, comprising a display substrate, a circuit board, a driver chip and the chip on film of claim 1,
wherein the chip on film comprises bonding areas in one-to-one correspondence with the display substrate, the driver chip and the circuit board.
